(19) United States
(12) Patent Application Publication
(10) Pub. No.: US 2025/0365933 A1
(43) Pub. Date: Nov. 27, 2025

(54) SEMICONDUCTOR DEVICES

(71) Applicant: Samsung Electronics Co., Ltd., Suwon-si (KR)

(72) Inventors: Hyunjin Lee, Suwon-si (KR); Donghyung Kim, Suwon-si (KR); Minsoo Kim, Suwon-si (KR); Seungmuk Kim, Suwon-si (KR); Yongkwan Kim, Suwon-si (KR); Jongmin Kim, Suwon-si (KR); Huijung Kim, Suwon-si (KR); Jiho Park, Suwon-si (KR)

(21) Appl. No.: 19/021,642

(22) Filed: Jan. 15, 2025

(30) Foreign Application Priority Data
May 22, 2024 (KR) 10-2024-0066329

(51) Int. Cl. H10B 12/00

(52) U.S. Cl. CPC H10B 12/315; H10B 12/05

(57) ABSTRACT

A semiconductor device includes: first and second active patterns on a bit line structure; a cell gate structure between the first and second active patterns; and a separation structure between the bit line structure and the cell gate structure. The cell gate structure includes: first and second gate electrodes adjacent to the first and second active patterns, respectively; an insulating layer between the first and second gate electrodes; and a gate dielectric layer on the first and second gate electrodes and the insulating layer. The gate dielectric layer includes: a first vertical portion between the first active pattern and the first gate electrode; a second vertical portion between the second active pattern and the second gate electrode; and an intermediate portion connected to the first and second vertical portions. The separation structure includes: liners between the intermediate portion and the bit line structure; and a capping layer between the liners.

### CROSS-REFERENCE TO RELATED APPLICATION(S)

This application claims the benefit of priority under 35 U.S.C. § 119 to Korean Patent Application No. 10-2024-0066329 filed on May 22, 2024, in the Korean Intellectual Property Office, the disclosure of which is incorporated herein by reference in its entirety.

### BACKGROUND

The present disclosure relates generally to a semiconductor device.

As demand for high performance, high speed, and/or multifunctionality in semiconductor devices increases, the degree of integration of semiconductor devices has increased. In manufacturing fine-patterned semiconductor devices in response to the trend of high integration of semiconductor devices, it is required to implement patterns having a fine width or a fine separation distance.

### SUMMARY

An aspect of the present disclosure is to provide a semiconductor device including a separation structure between a bit line and a gate structure.

As a means of addressing the above-mentioned aspect, an example embodiment of the present disclosure provides a semiconductor device including: a bit line structure; a first active pattern and a second active pattern on the bit line structure and spaced apart from each other; a cell gate structure between the first active pattern and the second active pattern; and a first separation structure between the bit line and the cell gate structure, wherein the cell gate structure includes: a first gate electrode adjacent to the first active pattern; a second gate electrode adjacent to the second active pattern; an insulating layer between the first and second gate electrodes; and a gate dielectric layer on at least portions of the first and second gate electrodes and the insulating layer; the gate dielectric layer includes: first vertical portions including a vertical portion between the first active pattern and the first gate electrode, and a vertical portion between the second active pattern and the second gate electrode; and a first intermediate portion connected to the first vertical portions and interposed between the first and second gate electrodes and the first separation structure, and the first separation structure includes: first liners spaced apart from each other between the first intermediate portion of the gate dielectric layer and the bit line; and a first capping layer between the first liners.

Furthermore, provided is a semiconductor device including: a first vertical active pattern and a second vertical active pattern spaced apart from each other; a gate structure between the first and second vertical active patterns; and an insulating structure on the gate structure, wherein the gate structure includes: at least one gate electrode; an insulating layer on the at least one gate electrode; and a gate dielectric layer on the at least one gate electrode and at least a portion of the insulating layer, wherein the gate dielectric layer includes: a first portion between the first vertical active pattern and the at least one gate electrode; a second portion between the second vertical active pattern and the at least one gate electrode; and a third portion connected to the first and second portions and interposed between the at least one gate electrode and the insulating structure, and wherein the insulating structure includes: liners spaced apart from each other on the third portion of the gate dielectric layer; and a capping layer between the liners.

Furthermore, provided is a semiconductor device including: a memory region and a peripheral region, wherein the memory region includes: a first vertical active pattern and a second vertical active pattern spaced apart from each other; a cell gate structure between the first and second vertical active patterns; and a separation structure on the cell gate structure, wherein the cell gate structure includes: a first gate electrode adjacent to the first vertical active pattern; a second gate electrode adjacent to the second vertical active pattern; an insulating layer between the first and second gate electrodes; and a gate dielectric layer on at least portions of the first and second gate electrodes and the insulating layer, wherein the separation structure includes: liners spaced apart from each other on a lower surface of the gate dielectric layer; and a capping layer between the liners, wherein the peripheral region includes an insulating structure including a lower portion and an upper portion on the lower portion, wherein the lower portion of the insulating structure includes: liner patterns spaced apart from each other on a lower surface of the upper portion; and a capping pattern between the liner patterns.

According to example embodiments of a technical concept of the present disclosure, provided is a semiconductor device including a separation structure between a bit line and a gate structure.

Specifically, provided is a semiconductor device including a first separation structure between a bit line and a cell gate structure and including insulating patterns and a second separation structure between the bit line and a back gate structure and including insulating patterns.

More specifically, according to the present disclosure, the first separation structure is formed before forming a cell gate electrode of the cell gate structure, and the second separation structure is formed before forming a back gate electrode of the back gate structure, thereby providing a semiconductor device having reduced vertical active pattern loss.

Advantages and effects of the present application are not limited to the foregoing content and may be more easily understood in the process of describing a specific example embodiment of the present disclosure.

### BRIEF DESCRIPTION OF THE DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 is a schematic plan view of a semiconductor device according to an example embodiment;

FIG. 2 is a schematic vertical cross-sectional view taken along line I-I′ of the semiconductor device illustrated in FIG. 1;

FIGS. 3A to 3C are partially enlarged schematic cross-sectional views of the semiconductor device illustrated in FIG. 2;

FIGS. 4A and 4B are partially enlarged schematic cross-sectional views of a semiconductor device according to an example embodiment;

FIGS. 5A and 5B are partially enlarged schematic cross-sectional views of a semiconductor device according to an example embodiment;

FIGS. 6A and 6B are partially enlarged schematic cross-sectional views of a semiconductor device according to an example embodiment;

FIGS. 7A and 7B are partially enlarged schematic cross-sectional views of a semiconductor device according to an example embodiment;

FIGS. 8 to 23 are schematic vertical cross-sectional views illustrating intermediate processes in a method of manufacturing a semiconductor device according to an example embodiment of the present disclosure;

FIGS. 24 to 30 are schematic vertical cross-sectional views illustrating intermediate processes in a method of manufacturing a semiconductor device according to an example embodiment of the present disclosure; and

FIGS. 31 to 36 are schematic vertical cross-sectional views illustrating intermediate processes in a method of manufacturing a semiconductor device according to an example embodiment of the present disclosure.

### DETAILED DESCRIPTION

Hereinafter, example embodiments of the present disclosure will be described with reference to the accompanying drawings.

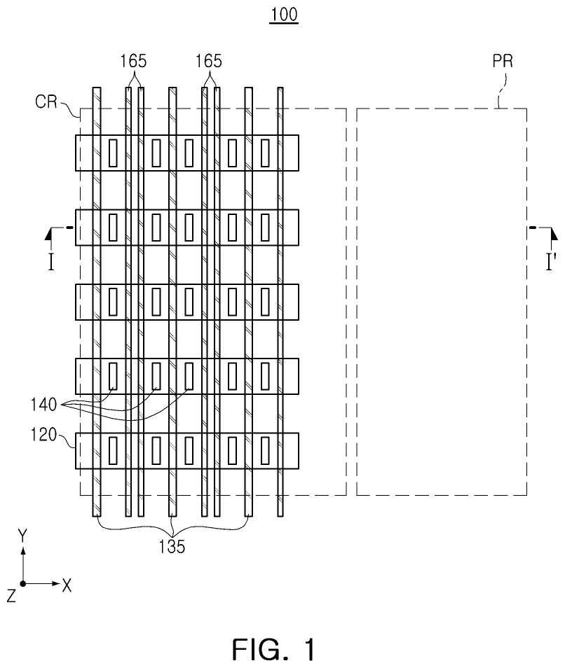

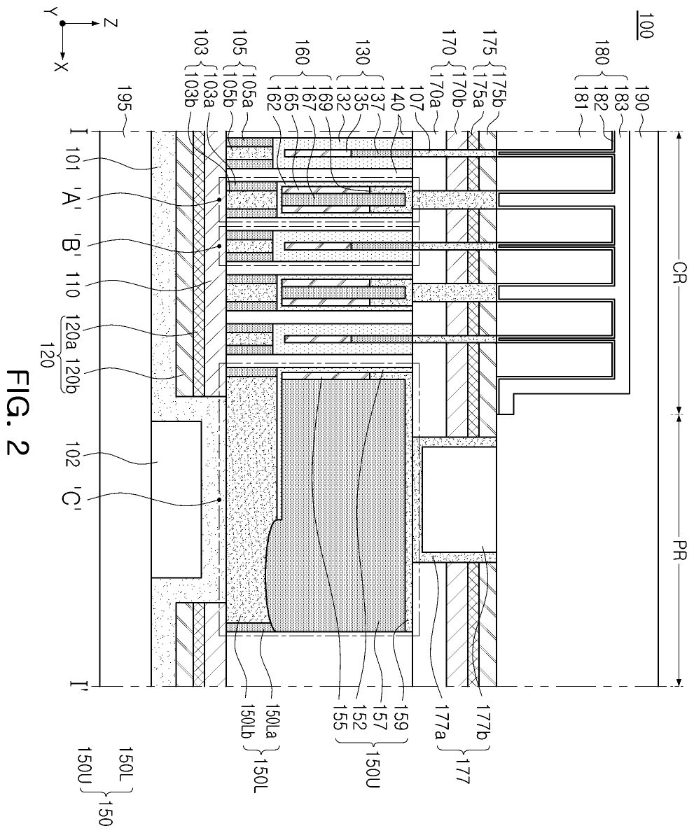

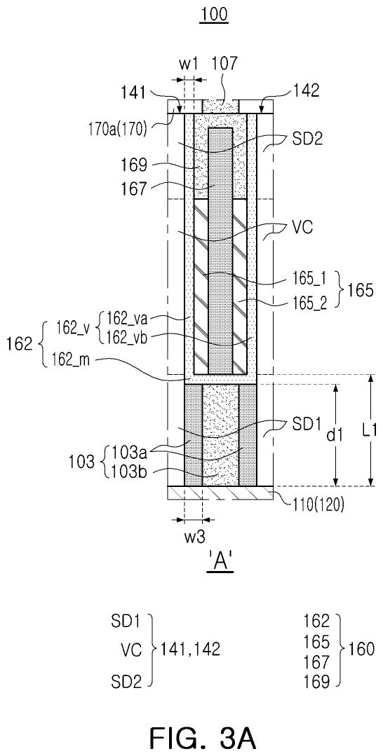

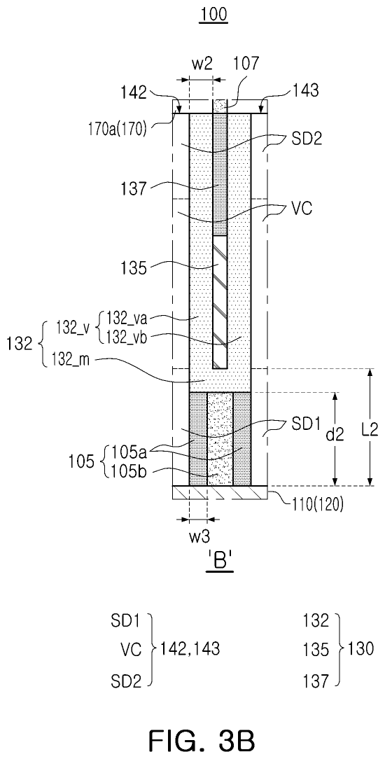

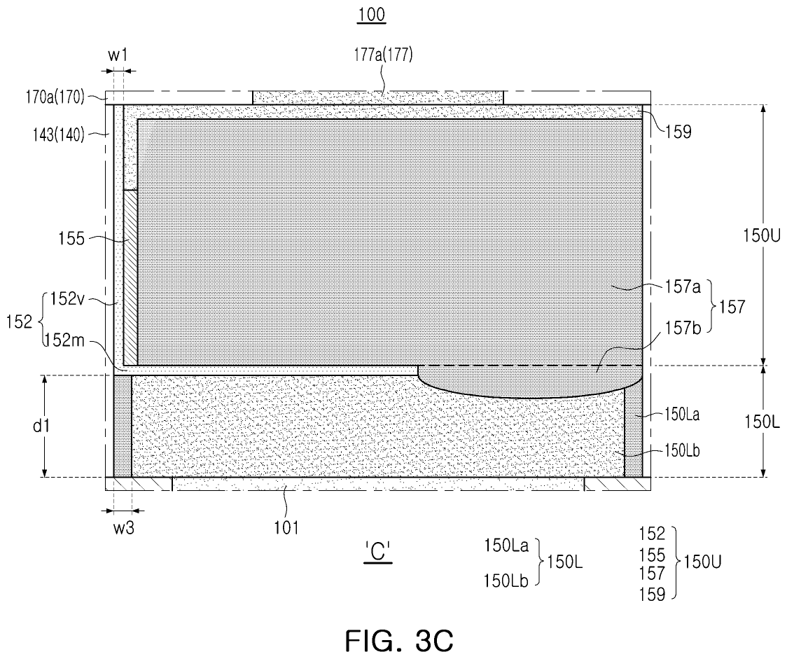

FIG. 1 is a schematic plan view of a semiconductor device according to an example embodiment. FIG. 2 is a schematic vertical cross-sectional view taken along line I-I′ of the semiconductor device illustrated in FIG. 1. FIG. 3A is a partially enlarged schematic cross-sectional view of region ‘A’ of the semiconductor device illustrated in FIG. 2. FIG. 3B is a partially enlarged schematic cross-sectional view of region ‘B’ of the semiconductor device illustrated in FIG. 2. FIG. 3C is a partially enlarged schematic cross-sectional view of region ‘C’ of the semiconductor device illustrated in FIG. 2.

Referring to FIGS. 1 to 3C, a semiconductor device 100 may include a memory region CR and a peripheral region PR.

The memory region CR may include an insulating layer 101, a bit line 120 extending in a first horizontal direction, for example, an X-direction, on the insulating layer 101, vertical (i.e., Z-direction) active patterns 140 spaced apart from each other on the bit line 120, cell upper source/drain patterns 170 disposed in an upper portion of the vertical active patterns 140, a cell lower source/drain pattern 110 disposed in a lower portion of the vertical active patterns 140, and back gate structures 130 and cell gate structures 160 disposed between vertical active patterns adjacent to each other in the first horizontal direction, among the vertical active patterns 140.

The semiconductor device 100 may further include a first separation structure 103 on the cell gate structures 160 and a second separation structure 105 on the back gate structures 130.

The semiconductor device 100 may include a vertical channel transistor comprised of vertical active patterns 140, a bit line 120 electrically connected to the vertical active patterns 140, and gate structures 130 and 160 disposed on at least one side of the vertical active patterns 140.

The semiconductor device 100 may be applied to, for example, a cell array of a Dynamic Random Access Memory (DRAM), but the present disclosure is not limited thereto.

The insulating layer 101 may include an insulating material such as silicon oxide, silicon nitride, silicon oxynitride (SiON), or silicon carbonitride (SiCN).

The bit line 120 may extend on the insulating layer 101 in the first horizontal direction (X-direction). In an example embodiment, the bit line 120 may be buried in the insulating layer 101. For example, the insulating layer 101 may cover side surfaces of the bit line 120. The term “cover” (or “covers,” or like terms), as may be used herein, is intended to broadly refer to an element, structure or layer that is on or over another element, structure or layer, either directly or with one or more other intervening elements, structures or layers therebetween.

The bit line 120 may be electrically connected to the vertical active pattern 140 through the cell lower source/drain pattern 110.

The bit line 120 may include doped polysilicon, a metal, conductive metal nitride, a metal-semiconductor compound, a conductive metal oxide, conductive graphene, carbon nanotubes, or combinations thereof. For example, the bit line 120 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, although embodiments are not limited thereto. In an example embodiment, the bit line 120 may include first and second conductive layers 120a and 120b sequentially stacked on the insulating layer 101 in the vertical direction (i.e., Z-direction).

The first conductive layer 120a may include, for example, a metal nitride such as titanium nitride (TiN) or a silicide material such as titanium silicide (TiSi). The second conductive layer 120b may include metallic materials such as titanium (Ti), tantalum (Ta), tungsten (W), and aluminum (Al). However, according to example embodiments, the materials included in the bit line 120, the number of layers thereof, and the cross-sectional thickness of the layers thereof may be variously changed.

The vertical active patterns 140 may be spaced apart from each other on the bit line 120 in the first horizontal direction (X-direction). The vertical active patterns 140 may include first to third vertical active patterns 141, 142, and 143 spaced apart from each other on the bit line 120. Each of the vertical active patterns 140 may include first and second source/drain regions and a vertical channel region between the first and second source/drain regions. For example, each of the first to third vertical active patterns 141, 142 and 143 may include a first source/drain region SD1 in contact with the cell lower source/drain patterns 110, a second source/drain region SD2 in contact with the cell upper source/drain patterns 170, and a vertical channel region VC between the first and second source/drain regions SD1 and SD2. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items.

In an example embodiment, the first and second source/drain regions SD1 and SD2 may have a first conductivity type, and the vertical channel region VC may have a second conductivity type different from the first conductivity type or may be an intrinsic region which is not doped. For example, the first conductivity type may be an N-type conductivity type, and the second conductivity type may be a P-type conductivity type.

In an example embodiment, the vertical active patterns 140 may include a single crystal semiconductor material. The single crystal semiconductor material may include a group IV semiconductor, a group III-V compound semiconductor, or a group II-VI compound semiconductor, and may include, for example, a single crystal semiconductor including at least one of silicon, silicon carbide, germanium, or silicon-germanium. However, according to example embodiments, the vertical patterns 140 may include at least one of a polycrystalline semiconductor material, an oxide semiconductor material such as indium gallium zinc oxide (IGZO), or a two-dimensional material such as MoS₂.

Referring to FIG. 3A, the first vertical active pattern 141 may be defined as being disposed in one side of the cell gate structure 160, and the second vertical active pattern 142 may be defined as being disposed on the other side of the cell gate structure 160 opposite to the one side. Referring to FIG. 3B, the second vertical active pattern 142 may be defined as being disposed on one side of the back gate structure 130, and the third vertical active pattern 143 may be defined as being disposed on the other side of the back gate structure 130 opposite to the one side. In other words, the second vertical active pattern 142 may be defined as a vertical active pattern between the gate structures 130 and 160 adjacent to each other.

Each of the cell upper source/drain patterns 170 may include a first cell upper source/drain pattern 170a and a second cell upper source/drain pattern 170b stacked sequentially. Side surfaces of the first cell upper source/drain pattern 170a and the second cell upper source/drain pattern 170b may be aligned. The first and second cell upper source/drain patterns 170a and 170b may vertically overlap the vertical active patterns 140 and may be in contact with the vertical active patterns 140. The term “overlap” (or “overlapping,” or like terms), as may be used herein, is intended to broadly refer to a first element that intersects with at least a portion of a second element in the vertical direction (i.e., Z-direction), but does not require that the first and second elements be completely aligned with one another in a horizontal plane (i.e., X-direction and/or Y-direction). The first and second cell upper source/drain patterns 170a and 170b may be of the first conductivity type. In other words, the first and second cell upper source/drain patterns 170a and 170b and the second source/drain region SD2 may be of the same conductivity type, and the second source/drain area SD2 may be a region defined by the first and second cell upper source/drain patterns 170a and 170b.

The cell lower source/drain pattern 110 vertically overlaps the vertical active patterns 140 on the bit line 120 and may be in contact the vertical active patterns 140. The cell lower source/drain pattern 110 may have the second conductivity type or may be the intrinsic region which is not doped. In other words, the cell lower source/drain pattern 110 and the first source/drain region SD1 may be of the same conductivity type, and the first source/drain area SD1 may be a region defined by the cell lower source/drain pattern 110. Accordingly, the bit line 120 may be electrically connected to the first source/drain region SD1 of the vertical active pattern 140 through the cell lower source/drain pattern 110. According to an example embodiment, the cell lower source/drain pattern 110 and bit line 120 may be collectively referred to as the bit line structure.

The cell gate structures 160 may be spaced apart from each other in a first horizontal direction (X-direction) and extend in a second horizontal direction (Y-direction) on both sides of the back gate structures 130. As described above, each of the vertical active patterns in both sides of the cell gate structures 160 may be referred to as first and second vertical active patterns 141 and 142.

Each of the cell gate structures 160 may include a gate dielectric layer 162, gate electrodes 165, and gate capping layers 167 and 169.

The gate electrodes 165 may include a first cell gate electrode 165_1 adjacent to the first vertical active pattern 141 and a second cell gate electrode 165_2 adjacent to the second vertical active pattern 142. The first and second cell gate electrodes 165_1 and 1652 may be spaced apart from each other in the first horizontal direction (X-direction) and extend in the second horizontal direction (Y-direction). Each of the first and second cell gate electrodes 165_1 and 165_2 may be spaced apart from the first and second vertical active patterns 141 and 142 by the gate dielectric layer 162. The first cell gate electrode 1651 may overlap the vertical channel region VC of the first vertical active pattern 141, and the second cell gate electrode 1652 may overlap the vertical channel region VC of the second vertical active pattern 142.

The gate electrodes 165 may include doped polysilicon, a metal, conductive metal nitride, a metal-semiconductor compound, conductive metal oxide, conductive graphene, carbon nanotubes or combinations thereof. For example, the gate electrodes 165 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotube, or combinations thereof, but the present disclosure is not limited thereto.

Lower surfaces of the gate electrodes 165 may be spaced apart from an upper surface of the cell lower source/drain pattern 110 by a first distance L1 in a vertical direction (Z-direction). According to an example embodiment, the first distance L1 may range from about 10 nm to about 100 nm. According to an example embodiment, the first distance L1 may range from about 10 nm to about 90 nm. According to an example embodiment, the first distance L1 may range from about 10 nm to about 80 nm.

The gate dielectric layer 162 may include first vertical portions 162_v and a first intermediate portion 162_m connected to the first vertical portions 162_v.

The first vertical portions 162_v may include a vertical portion 162_va between the first vertical active pattern 141 and the first gate cell electrode 165_1, and a vertical portion 162_vb between the second vertical active pattern 142 and the second gate cell electrode 165_2. Each of the vertical portions 162_va and 162_vb may extend on the first and second vertical active patterns 141 and 142 in the vertical direction (Z-direction) and may be in contact with a lower surface of the cell upper source/drain pattern 170.

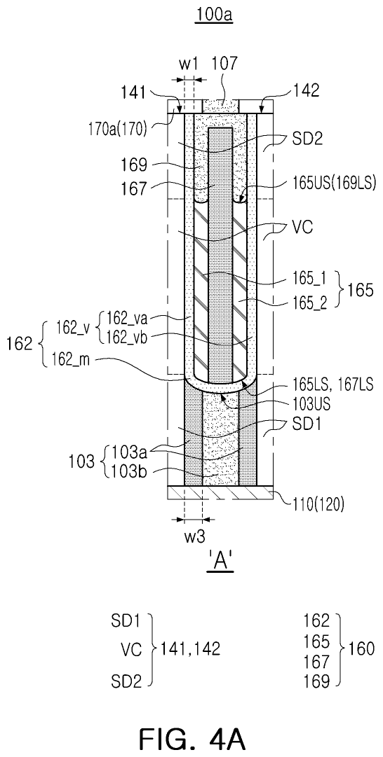

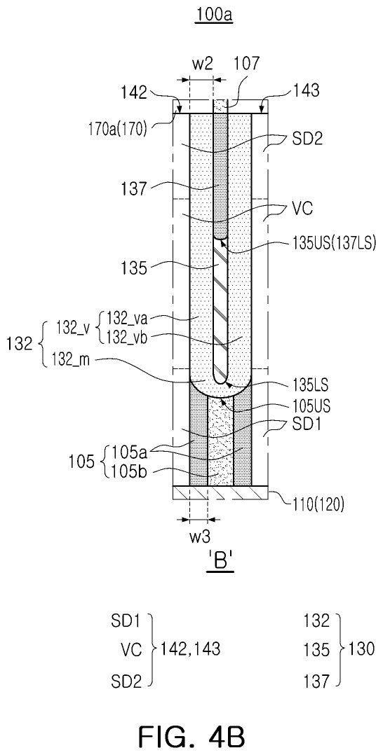

The first intermediate portion 162_m may connect lower portions of the vertical portions 162_va and 162_vb, and may be disposed between the gate electrodes 165 and the first separation structure 103. The first intermediate portion 162_m may extend horizontally between the gate electrodes 165 and the first separation structure 103, but the present disclosure is not limited thereto. According to an example embodiment, the first intermediate portion 162_m may have an upper surface and a lower surface that are convex toward the first separation structure 103 (see FIG. 4A).

The gate dielectric layer 162 may have a uniform thickness. For example, the first vertical portions 162_v and the first intermediate portion 162_m may have the same first width w1.

The gate dielectric layer 162 may include at least one of oxide (for example, silicon oxide) and high-x dielectric. The high-x dielectric may include metal oxide or metal oxynitride. For example, the high-K dielectric may be formed of HfO₂, HfSiO, HfSiON, HfTaO, HfTiO, HfZrO, ZrO₂, Al₂O₃, or combinations thereof, but the present disclosure is not limited thereto. The gate dielectric layer 162 may be formed of a single layer or multiple layers of the materials described above.

The gate capping layers 167 and 169 may include a first gate capping layer 167 between the first and second cell gate electrodes 165_1 and 165_2, and a second gate capping layer 169 covering the first and second cell gate electrodes 165_1 and 165_2 and the first gate capping layer 167. An upper region of the first gate capping layer 167 may be disposed on a vertical level higher than that of upper surfaces of the first and second cell gate electrodes 165_1 and 165_2, relative to an upper surface of the bit line 120 as a reference layer, and may be disposed on a vertical level lower than that of upper surfaces of the first vertical portions 162_v of the gate dielectric layer 162, relative to the upper surface of the bit line 120. Accordingly, the second gate capping layer 169 may cover the upper surfaces of the first and second cell gate electrodes 165_1 and 165_2, and may cover an upper surface and a side surface of the upper region of first gate capping layer 167. The first gate capping layer 167 may be formed of an insulating oxide, for example, silicon oxide, and the second gate capping layer 169 may be formed of an insulating nitride, for example, silicon nitride.

The first separation structures 103 may be disposed between the bit line 120 (or ‘cell lower source/drain pattern 110’) and the cell gate structures 160, and may separate the cell gate structures 160 from the bit line 120 in the vertical direction (Z-direction). A side surface of the first separation structure 103 may be aligned with a side surface of the cell gate structure 160.

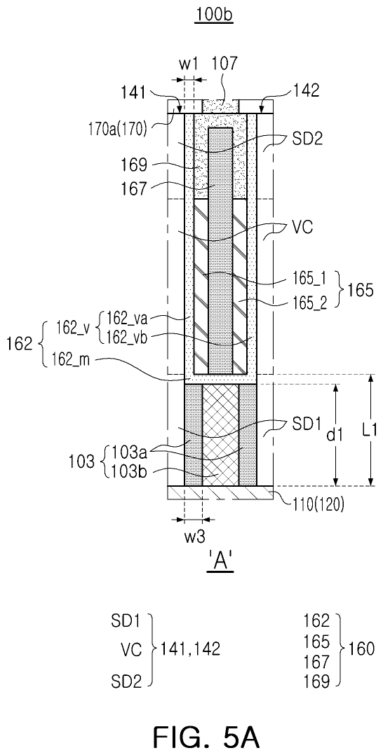

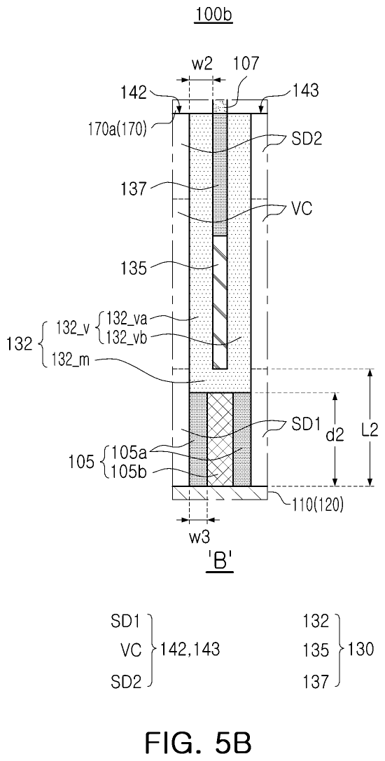

The first separation structure 103 may include first liners 103a spaced apart from each other in the first horizontal direction (X-direction) between the first intermediate portion 162_m of the gate dielectric layer 162 and the bit line 120, and a first capping layer 103b between the first liners 103a. The first liners 103a may be formed of an insulating oxide, for example, silicon oxide, and the first capping layer 103b may be formed of an insulating nitride, for example, silicon nitride, but the present disclosure is not limited thereto. For example, the first capping layer 103b may be formed of an insulating oxide, for example, silicon oxide (see FIG. 5). Each of the first liners 103a may have a third width w3 in the horizontal direction.

The first separation structure 103 may have a first thickness d1 in the vertical direction (Z-direction). The first thickness d1 may be smaller than the first distance L1. For example, the first thickness d1 may be at most about 10 nm smaller than the first distance L1. According to an example embodiment, the first thickness d1 may range from about 10 nm to about 90 nm. According to an example embodiment, the first thickness d1 may range from about 10 nm to about 80 nm. According to an example embodiment, the first thickness d1 may range from about 10 nm to about 70 nm.

The back gate structures 130 may be spaced apart from each other in the first horizontal direction (X-direction), and may extend on both sides of the cell gate structures 160 in the second horizontal direction (Y-direction). As described above, each of the vertical active patterns in both sides of the back gate structures 130 may be referred to as second and third vertical active patterns 142 and 143.

Each of the back gate structures 130 may include a back gate dielectric layer 132, a back gate electrode 135, and a back gate capping layer 137.

The back gate electrode 135 may overlap the vertical channel regions VC of the second and third vertical active patterns 142 and 143.

A lower surface of the back gate electrode 135 may be spaced apart from an upper surface of the cell lower source/drain pattern 110 by a second distance L2 in the vertical direction (Z-direction). The second distance L2 may have substantially the same size as the first distance L1. According to an example embodiment, the second distance L2 may range from about 10 nm to about 100 nm. According to an example embodiment, the second distance L2 may range from about 10 nm to about 90 nm. According to an example embodiment, the second distance L2 may range from about 10 nm to about 80 nm.

The back gate electrode 135 may include doped polysilicon, a metal, conductive metal nitride, a metal-semiconductor compound, a conductive metal oxide, conductive graphene, carbon nanotubes or combinations thereof. For example, the back gate electrodes 135 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotube, or combinations thereof, but the present disclosure is not limited thereto.

The back gate dielectric layer 132 may include second vertical portions 132_v and a second intermediate portion 132_m connected to the second vertical portions 132_v.

The second vertical portions 132_v may include a vertical portion 132_va between the second vertical active pattern 142 and the back gate electrode 135, and a vertical portion 132_vb between the third vertical active pattern 143 and the back gate electrode 135. Each of the vertical portions 132_va and 132_vb may extend on the second and third vertical active patterns 142 and 143 in the vertical direction (Z-direction) and may be in contact with the lower surface of the cell upper source/drain pattern 170.

The second intermediate portion 132_m connects lower portions of the vertical portions 132_va and 132_vb, and may be disposed between the back gate electrode 135 and the second separation structure 105. The second intermediate portion 132_m may extend horizontally between the back gate electrode 135 and the second separation structure 105, but the present disclosure is not limited thereto. According to an example embodiment, the second intermediate portion 132_m may have an upper surface and a lower surface that are convex toward the second separation structure 105 (see FIG. 4B).

The second vertical portions 132_v and the second intermediate portion 132_m may have the same second width w2. Here, the second width w2 may be greater than the first width w1.

The back gate dielectric layer 132 may include at least one of oxide (for example, silicon oxide) and high-x dielectric. The high-x dielectric may include metal oxide or metal oxynitride. For example, the high-K dielectric may be made of HfO₂, HfSiO, HfSiON, HfTaO, HfTiO, HfZrO, ZrO₂, Al₂O₃, or combinations thereof, but the present disclosure is not limited thereto. The back gate dielectric layer 132 may be formed of a single layer or multiple layers of the materials described above.

The back gate capping layer 137 may cover an upper surface of the back gate electrode 135 between the second vertical portions 132_v of the back gate dielectric layer 132. An upper surface of the back gate capping layer 137 may be on substantially the same level as upper surfaces of the second vertical portions 132_v of the back gate dielectric layer 132; that is, the upper surface of the back gate capping layer 137 may be coplanar with the upper surfaces of the second vertical portions 132_v of the back gate dielectric layer 132, relative to the upper surface of the bit line 120 as a reference layer. The back gate capping layer 137 may be formed of an insulating oxide, for example, silicon oxide.

The second separation structures 105 are disposed between the bit line 120 (or ‘cell lower source/drain pattern 110’) and the back gate structures 130, and may separate the back gate structures 130 from the bit line 120 in the vertical direction (Z-direction). A side surface of the second separation structure 105 may be aligned with a side surface of the back gate structure 130.

The second separation structure 105 may include second liners 105a spaced apart from each other between the second intermediate portion 132_m of the back gate dielectric layer 132 and the bit line 120 in the first horizontal direction (X-direction), and a second capping layer 105b between the second liners 105a. The second liners 105a may include the same material as the first liners 103a, and the second capping layer 105b may include the same material as the first capping layer 103b. Accordingly, the second liners 105a may be formed of an insulating oxide, for example, silicon oxide, and the second capping layer 105b may be formed of an insulating nitride, for example, silicon nitride. According to an example embodiment, the second capping layer 105b may be formed of an insulating oxide, for example, silicon oxide (see FIG. 5B).

Each of the second liners 105a may have a width equal to a horizontal width of each of the first liners 103a. For example, each of the second liners 105a may have a third width w3 in the horizontal direction (X-direction).

The third width w3 may be different from the first width w1, and the third width w3 may be different from the second width w2. In other words, the third width w3 may be substantially equal to the first width w1 or may be greater than the first width w1, and the third width w3 may be substantially equal to the second width w2 or may be smaller than the second width w2.

The second separation structure 105 may have a second thickness d2 in the vertical direction (Z-direction). The second thickness d2 may be smaller than the second distance L2. For example, the second thickness d2 may be at most about 10 nm smaller than the second distance L2. According to an example embodiment, the second thickness d2 may range from about 10 nm to about 90 nm. According to an example embodiment, the second thickness d2 may range from about 10 nm to about 80 nm. According to an example embodiment, the second thickness d2 may range from about 10 nm to about 70 nm.

The memory region CR may further include contact plugs 175. The contact plugs 175 may be disposed on the cell upper source/drain patterns 170. Each of the contact plugs 175 may include a metal-semiconductor compound layer 175a in contact with an upper surface of the second cell upper source/drain pattern 170b, and a plug pattern 175b on the metal-semiconductor compound layer 175a. The cell upper source/drain patterns 170 and the contact plugs 175, which are sequentially stacked in the vertical direction (Z-direction), may have side surfaces that are aligned with each other. The contact plugs 175 may be aligned with and may be in contact with the cell upper source/drain patterns 170.

The memory region CR may further include separation patterns 107. The separation patterns 107 may define side surfaces of the cell upper source/drain patterns 170 and the contact plugs 175 that are sequentially stacked. The separation patterns 107 may surround side surfaces of the cell upper source/drain patterns 170 and the contact plugs 175 that are sequentially stacked. The term “surround” (or “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. Each of the separation patterns 107 may be disposed on the same vertical level as each other and may include the same insulating materials as each other. For example, each of the separation patterns 107 may include insulating nitride.

The memory region CR may further include information storage structures 180 and an insulating layer 190.

The information storage structure 180 may include first electrodes 181 connected to the contact plugs 175 in the memory region CR and extending in the vertical direction (Z-direction), second electrodes 183 on side surfaces and upper surfaces of each of the first electrodes 181, and a dielectric layer 182 between the first electrodes 181 and the second electrodes 183. The information storage structure 180 may be a cell capacitor of a memory such as DRAM.

The insulating layer 190 may cover the information storage structure 180 in the memory region CR. The insulating layer 190 may include at least one of silicon oxide or low-x dielectric.

The peripheral region PR may include an insulating structure 150. The insulating structure 150 may include a lower insulating pattern 150L and an upper insulating pattern 150U on the lower insulating pattern 150L.

The lower insulating pattern 150L may include liner patterns 150La spaced apart from each other on a lower surface of the upper insulating pattern 150U in the first horizontal direction (X-direction), and a capping pattern 150Lb between the liner patterns 150La. Each of the liner patterns 150La may have a width substantially equal to widths of each of the first liners 103a of the first separation structure 103 and widths of each of the second liners 105a of the second separation structure 105. That is, each of the liner patterns 150La may have the third width w3 in the first horizontal direction (X-direction). The liner patterns 150La may include the same material as the first and second liners 103a and 105a. That is, the liner patterns 150La may be formed of an insulating oxide, for example, silicon oxide. The capping pattern 150Lb may include the same material as the first and second capping layers 103b and 105b. That is, the capping pattern 150Lb may be formed of an insulating nitride, for example, silicon nitride.

The lower insulating pattern 150L may have substantially the same thickness as the first separation structure 103 in the vertical direction (Z-direction). That is, the lower insulating pattern 150L may have the first thickness d1. In other words, upper surfaces of the liner patterns 150La may be on substantially the same level as upper surfaces of the first liners 103a, and an upper surface of the capping pattern 150Lb may be on substantially the same level as (i.e., coplanar with) an upper surface of the first capping layer 103b.

The upper insulating pattern 150U may include a plurality of insulating patterns 152, 157 and 159 and a conductive pattern 155.

The insulating pattern 152 may include a vertical portion 152v extending on the vertical active pattern 140 in the vertical direction (Z-direction), and a horizontal portion 152m extending in the first horizontal direction (X-direction) from an end of a lower region of the vertical portion 152v. The vertical portion 152v of the insulating pattern 152 may have an upper surface in contact with a lower surface of the first cell upper source/drain pattern 170a, and may overlap with the liner patterns 150La. The horizontal portion 152m of the insulating pattern 152 may be connected to the vertical portion 152v and may extend on at least a portion of the lower insulating pattern 150L in the first horizontal direction (X-direction). An end of the horizontal portion 152m of the insulating pattern 152 may be disposed on the capping pattern 150Lb.

An upper surface of the vertical portion 152v may be on substantially the same level as (i.e., coplanar with) an upper surface of each of the first vertical portions 162_v of the gate dielectric layer 162. A lower surface of the horizontal portion 152m may be on substantially the same level as (i.e., coplanar with) a lower surface of the first intermediate portion 162_m of the gate dielectric layer 162. The vertical portion 152v and the horizontal portion 152m may have the same width as the first width w1 of the gate dielectric layer 162. The insulating pattern 152 and the gate dielectric layer 162 may include the same insulating material.

The conductive pattern 155 may be on a side surface of the vertical portion 152v on the horizontal portion 152m. An upper surface of the conductive pattern 155 may be on substantially the same level as upper surfaces of the first and second cell gate electrodes 165_1 and 1652, and a lower surface of the conductive pattern 155 may be on substantially the same level as lower surfaces of the first and second cell gate electrodes 165_1 and 165_2.

The insulating pattern 157 may include a first portion 157a on the lower insulating pattern 150L, and a second portion 157b having a lower surface formed to be convex downwardly by protruding in a vertical direction downwardly from at least a portion of a lower region of the first portion 157a. Accordingly, a level of a lowermost surface of the second portion 157b may be lower than a level of the lower surface of the horizontal portion 152m in the vertical direction (Z-direction). An upper surface of the insulating pattern 157 may be on a lower level than the upper surface of the vertical portion 152v. The insulating pattern 157 may include the same material as that of the first gate capping layer 167 of the cell gate structure 160.

The insulating pattern 159 may include a portion covering the upper surface of the conductive pattern 155 and extending in the vertical direction (Z-direction) between the vertical portion 152v of the insulating pattern 152 and the first portion 157a of the insulating pattern 157, and a portion extending in the first horizontal direction (X-direction) on an upper surface of the first portion 157a of the insulating pattern 157.

The lower insulating pattern 150L and the upper insulating pattern 150U may be aligned.

The peripheral region PR may further include an insulating structure 177 in an upper portion of the insulating structure 150. The insulating structure 177 may further include an insulating pattern 177b and an insulating liner 177a covering a side surface and a lower surface of the insulating pattern 177b. The insulating pattern 177b may include oxide, and the insulating liner 177a may include nitride.

The insulating layer 190 of the memory region CR may extend horizontally (e.g., in the X-direction) into the peripheral region PR. Accordingly, the insulating layer 190 may cover an upper surface of the insulating structure 177 in the peripheral region PR.

The insulating layer 101 of the memory region CR may extend horizontally into the peripheral region PR. The insulating layer 101 may cover side surfaces of the bit line 120 and a lower surface of the insulating structure 150 in the peripheral region PR.

The peripheral region PR may further include an insulating pattern 102. The side surfaces and upper surface of the insulating pattern 102 may be covered with the insulating layer 101.

The memory region CR and the peripheral region PR may further include an insulating layer 195 disposed on lower portions of the insulating layer 101 and the insulating pattern 102.

Hereinafter, referring to FIGS. 4A to 7B, various modified examples of the components of the above-described embodiment will be described. Various modifications of the components of the above-described embodiments described below will be described with a focus on modified or replaced components. In addition, components that may be modified or replaced, as described below, will be described with reference to the attached drawings, but the components that may be modified or replaced may be combined with each other or with the components described above to configure a semiconductor device according to an example embodiment of the present disclosure.

FIGS. 4A and 4B are partially enlarged views of a semiconductor device according to an example embodiment. FIG. 4A illustrates an enlarged view of a region corresponding to region ‘A’ in FIG. 2. FIG. 4B illustrates an enlarged view of a region corresponding to region ‘B’ in FIG. 2.

Referring to FIGS. 4A and 4B, a semiconductor device 100a may be identical to or similar to that described with reference to FIGS. 1 to 3C, except that each of separation structures 103 and 105 has upper surfaces formed to be convex downwardly, and each of the gate electrodes 135 and 165 has upper surfaces formed to be convex downwardly.

Referring to FIG. 4A, an upper surface 103US of the first separation structure 103 may have a convex shape toward a lower cell source/drain pattern 110. Accordingly, a first intermediate portion 162_m of a gate dielectric layer 162 may have a convex shape toward the first separation structure 103. Similarly, each of cell gate electrodes 165_1 and 165_2 and a first gate capping layer 167 may have lower surfaces 165LS and 167LS bent downwardly.

Meanwhile, in an example embodiment, each of the cell gate electrodes 165_1 and 165_2 may have a convex upper surface 165US toward the first separation structure 103. Accordingly, the second gate capping layer 169 may have lower surfaces 169LS formed to be convex toward the cell gate electrodes 165_1 and 165_2, on the cell gate electrodes 165_1 and 165_2.

Referring to FIG. 4B, an upper surface 105US of the second separation structure 105 may have a convex shape toward the lower cell source/drain pattern 110. Accordingly, a second intermediate portion 132_m of a back gate dielectric layer 132 may have a convex shape toward the second separation structure 105. Similarly, the back gate electrode 135 may have a lower surface 135LS formed to be convex downwardly.

Meanwhile, in an example embodiment, the back gate electrode 135 may have an upper surface 135US formed to be convex toward the second separation structure 105. Accordingly, the back gate capping layer 137 may have a lower surface 137LS formed to be convex toward the back gate electrode 135, on the back gate electrode 135.

FIGS. 5A and 5B are partially enlarged views of a semiconductor device according to an example embodiment. FIG. 5A illustrates an enlarged view of a region corresponding to region ‘A’ in FIG. 2. FIG. 5B illustrates an enlarged view of the region corresponding to region ‘B’ in FIG. 2.

Referring to FIGS. 5A and 5B, in a semiconductor device 100b may be identical to or similar to that described with reference to FIGS. 1 to 4B, except that a first capping layer 103b of a first separation structure 103 and a second capping layer 105b of a second separation structure 105 include an insulating oxide.

Referring to FIG. 5A, a first capping layer 103b may include an insulating oxide, for example, silicon oxide. Accordingly, first liners 103a and the first capping layer 103b may include the same insulating material, but boundaries thereof may be distinct from each other.

Referring to FIG. 5B, a second capping layer 105b may include an insulating oxide, for example, silicon oxide. Similarly, second liners 105a and the second capping layer 105b may include the same insulating material, but boundaries thereof may be distinct from each other.

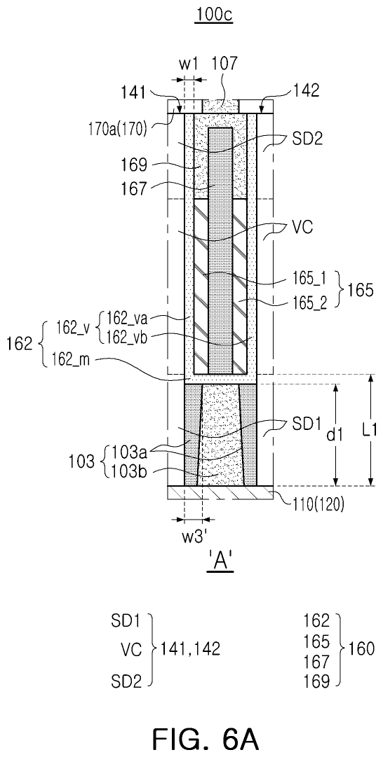

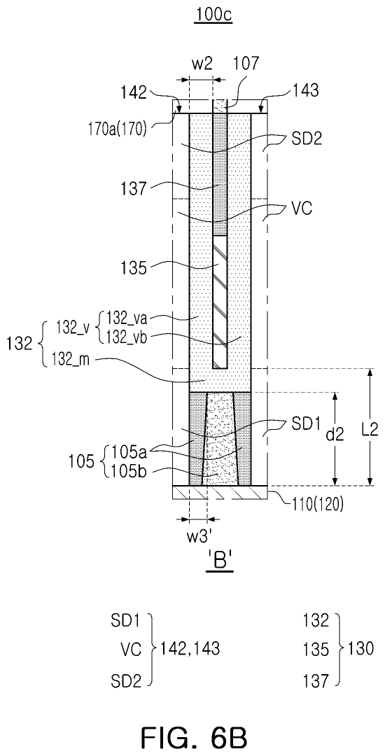

FIGS. 6A and 6B are partially enlarged views of a semiconductor device according to an example embodiment. FIG. 6A illustrates an enlarged view of a region corresponding to region ‘A’ in FIG. 2. FIG. 6B illustrates an enlarged view of a region corresponding to region ‘B’ in FIG. 2.

Referring to FIGS. 6A and 6B, a semiconductor device 100c may be identical to or similar to that described with reference to FIGS. 1 to 5B, except that each width of first liners 103a of a first separation structure 103 and each width of second liners 105a of a second separation structure 105 may vary in the vertical direction (Z-direction).

Referring to FIG. 6A, widths w3′ of each of the first liners 103a of the first separation structure 103 may decrease as a distance from a lower surface of a first intermediate portion 162_m of a gate dielectric layer 162 toward an upper surface of a cell lower source/drain pattern 110 increases in the vertical direction (Z-direction). Complementarily, a horizontal width (e.g., in the X-direction) of a first capping layer 103b of the first separation structure 103 may increase as a distance from a lower surface of the first intermediate portion 162_m of the gate dielectric layer 162 toward an upper surface of the cell lower source/drain pattern 110 increases in the vertical direction (Z-direction).

Referring to FIG. 6B, widths w3′ of each of the second liners 105a of the second separation structure 105 may decrease as a distance from a lower surface of a second intermediate portion 132_m of a back gate dielectric layer 132 toward the upper surface of the cell lower source/drain pattern 110 increases in the vertical direction (Z-direction). Complementarily, a horizontal width of a second capping layer 105b of the second separation structure 105 may increase as a distance from the lower surface of the second intermediate portion 132_m of the back gate dielectric layer 132 toward the upper surface of the cell lower source/drain pattern 110 increases in the vertical direction (Z-direction).

In an example embodiment, the lower surfaces of each of the first and second liners 103a and 105a may be in contact with the upper surface of the cell lower source/drain pattern 110.

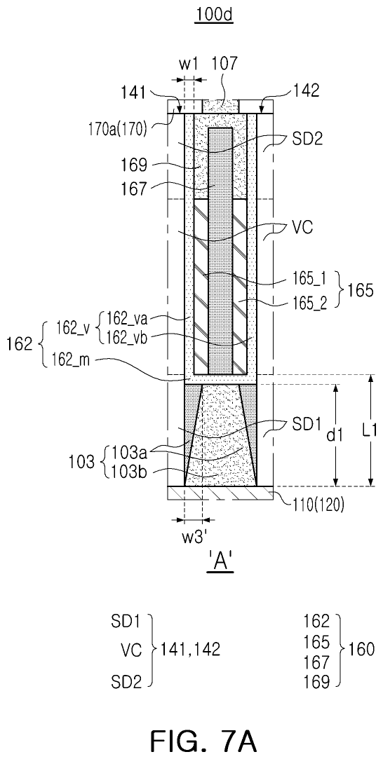

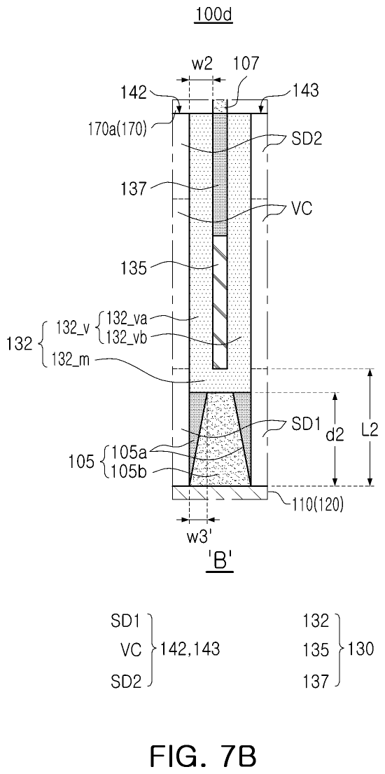

FIGS. 7A and 7B are partially enlarged views of a semiconductor device according to an example embodiment. FIG. 7A illustrates an enlarged view of a region corresponding to region ‘A’ in FIG. 2. FIG. 7B illustrates an enlarged view of a region corresponding to region ‘B’ in FIG. 2.

Referring to FIGS. 7A and 7B, a semiconductor device 100d may be identical to or similar to that described with reference to FIGS. 1 to 6B, except that lower surfaces of first liners 103a of a first separation structure 103 and lower surfaces of second liners 105a of a second separation structure 105 are not in contact with an upper surface of a cell lower source/drain pattern 110.

Referring to FIGS. 7A and 7B, especially similarly to FIGS. 6A and 6B, widths w3′ of each of first liners 103a of a first separation structure 103 and widths w3′ of each of second liners 105a of a second separation structure 105 may decrease as a vertical distance from an upper surface of a cell lower source/drain pattern 110 decreases.

Comparing FIGS. 7A and 7B with FIGS. 6A and 6B, the lower surfaces of the first liners 103a of the first separation structure 103 and the lower surfaces of the second liners 105a of the second separation structure 105 may not be in contact the upper surface of the cell lower source/drain pattern 110.

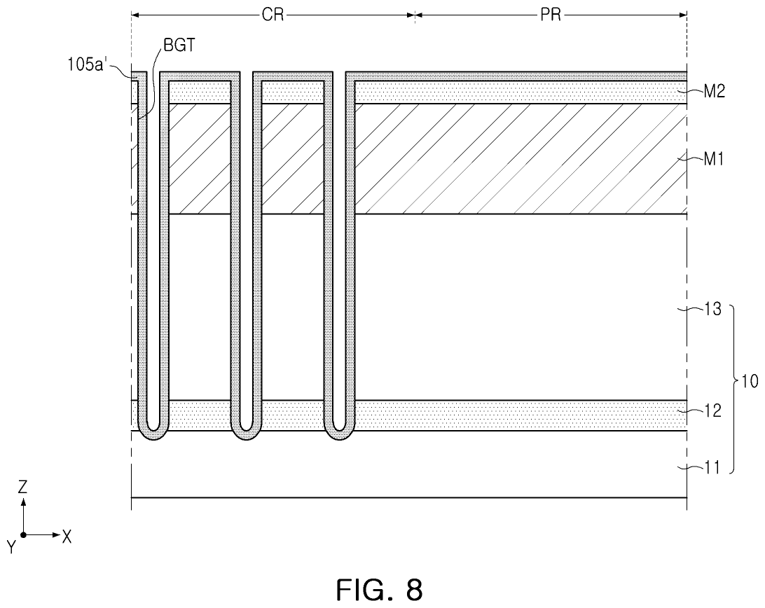

FIGS. 8 to 23 are vertical cross-sectional views illustrating intermediate processes in a method of manufacturing a semiconductor device according to an example embodiment of the present disclosure.

Referring to FIG. 8, a semiconductor substrate 10 and a plurality of masks M1 and M2 sequentially stacked on the semiconductor substrate 10 may be provided.

The semiconductor substrate 10 may be a silicon on insulator (SOI) substrate. The semiconductor substrate 10 may include a lower semiconductor layer 11, an insulating layer 12, and an upper semiconductor layer 13. For example, the upper and lower semiconductor layers 11 and 13 may include single crystal silicon.

The masks M2 and M1 may be configured to be used in an etching process subsequently performed to form a back gate trench BGT.

Next, the back gate trench BGT may be formed in the semiconductor substrate 10, and a preliminary insulating layer 105a′ may be formed in the back gate trench BGT.

An etching process using the mask M2 may be performed to form the back gate trench BGT penetrating through (i.e., extending in) the upper semiconductor layer 13 and the insulating layer 12 and exposing an upper surface of the lower semiconductor layer 11 through at least a bottom of the back gate trench BGT. The term “exposing” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The back gate trench BGT may be formed to have a line shape extending in the second horizontal direction (Y-direction).

The preliminary insulating layer 105a′ may be formed on a sidewall of the back gate trench BGT. The preliminary insulating layer 105a′ may be deposited to substantially conformally cover an upper surface and a side surface of the mask M2, a side surface of the mask M1, a side surface of the upper semiconductor layer 13, a side surface of the insulating layer 12, and an upper surface of the lower semiconductor layer 11. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The preliminary insulating layer 105a′ may be formed by depositing an insulating material such as silicon oxide, silicon nitride, silicon oxynitride (SiON), or silicon carbonitride (SiCN). In this example embodiment, the preliminary insulating layer 105a′ may be formed of silicon oxide.

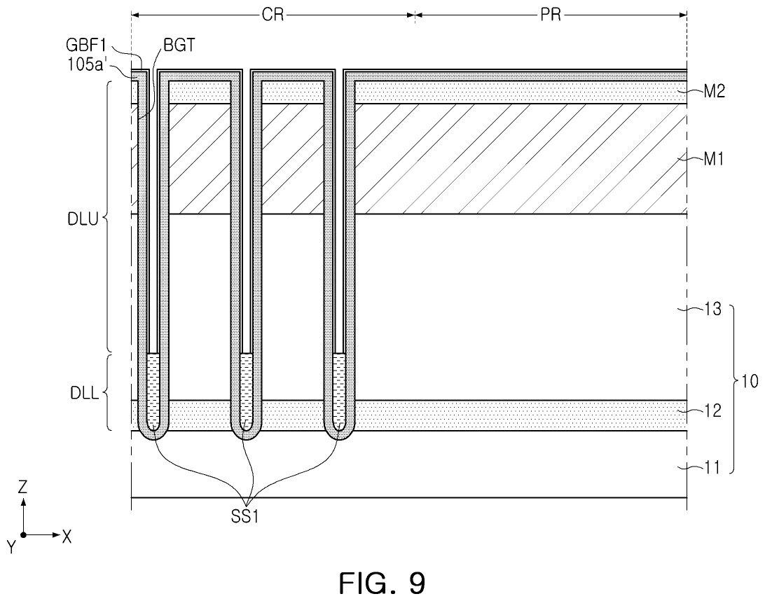

Referring to FIG. 9, a growth prevention film GBF1 may be formed on a surface of an upper region of the preliminary insulating layer 105a′, and a substitution structure SS1 may be grown on a surface of a lower region of the preliminary insulating layer 105a′.

The growth prevention film GBF1 may be formed on a sidewall of a portion DLU (which may be referred to as an ‘upper portion’) equal to or greater than a desired level from a lower surface of the back gate trench BGT, among sidewalls of the preliminary insulating layer 105a′. This may be achieved using a large aspect ratio of the back gate trench BGT. At least one cycle may proceed so that the growth prevention film GBF1 may be formed on the sidewall of the portion DLU equal to or greater than the desired level. The growth prevention film GBF1 may be formed by chemical vapor deposition (CVD) using gaseous hydrogen (H₂).

Here, the growth prevention film GBF1 may be configured to selectively form the substitution structure SS1 on a surface of a portion DLL (which may be referred to as a ‘lower portion’) equal to or less than the desired level from the lower surface of the back gate trench BGT, among surfaces of the preliminary insulating layer 105a′.

Subsequently, the substitution structure SS1 may be grown from a lower surface and a sidewall of the lower portion DLL of the preliminary insulating layer 105a′. A highly reactive and desired substitution material (or a predetermined substitution material) (e.g., a radical) may form an island on the lower surface and the sidewall of the lower portion DLL, and then, the island gradually may be grown, and the substitution structure SS1 may be formed. The substitution structure SS1 may be grown by a level at which the growth prevention film GBF1 is formed. The substitution material may include carbon, and the substitution structure SS1 may be referred to as an amorphous carbon layer.

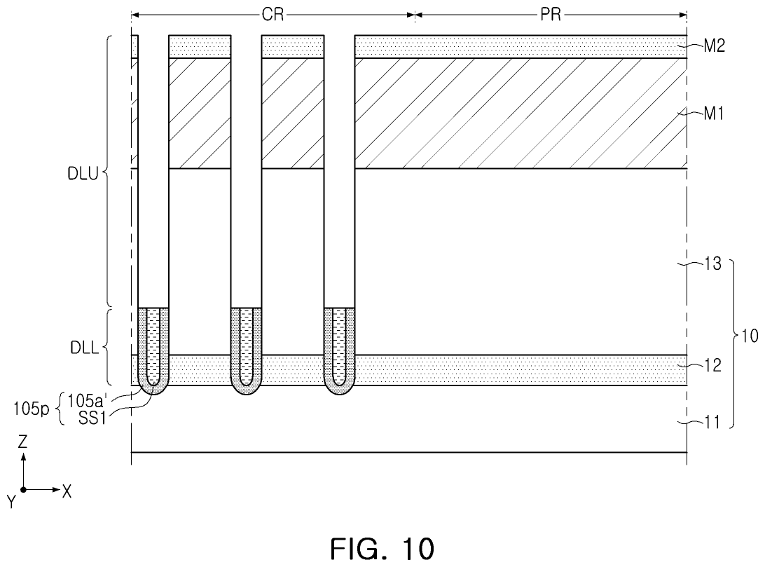

Referring to FIG. 10, the upper portion DLU of the preliminary insulating layer 105a′ and the growth prevention film GBF1 may be removed.

Referring to FIG. 9 and FIG. 10 together, the upper portion DLU of the preliminary insulating layer 105a′ and the growth prevention film GBF1 may be removed in an etching process. Accordingly, a preliminary second separation structure 105p including the preliminary insulating layer 105a′ and the substitution structure SS1 may be formed in the lower region of the back gate trench BGT. Meanwhile, through the etching, the preliminary second separation structure 105p may have a downwardly convex upper surface (see FIG. 4B).

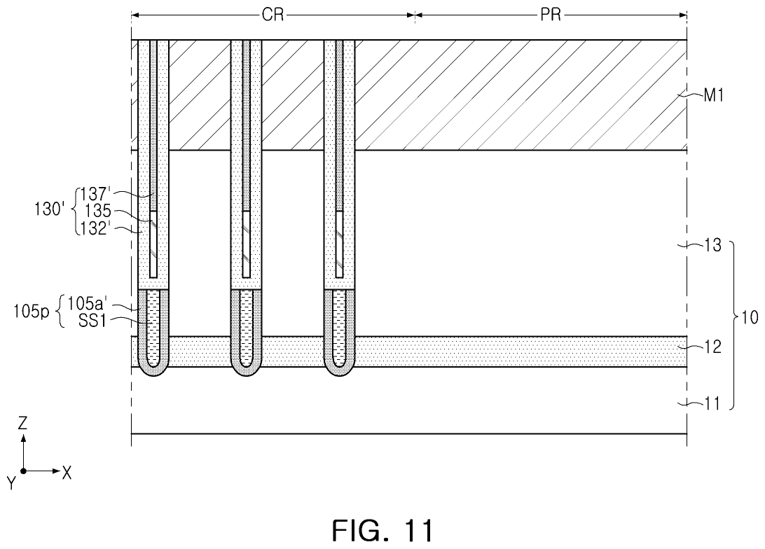

Referring to FIG. 11, a preliminary back gate structure 130′ may be formed in the back gate trench BGT (see FIG. 10).

A preliminary back gate insulating layer 132′ may be formed on a sidewall and a lower surface of the back gate trench BGT. Next, a conductive material may be filled into the back gate trench BGT, and then, an etch-back process may be performed to form the back gate electrode 135. The term “filled” (or “filling,” or like terms) is intended to refer to either completely filling a defined space (e.g., the back gate trench BGT) or partially filling the defined space; that is, the defined space need not be entirely filled but may, for example, be partially filled or have voids or other spaces throughout. Next, an insulating material may be filled therein to cover the upper surface of the back gate electrode 135, thus forming a preliminary back gate capping layer 137′. Then, a planarization process may be performed so that the preliminary back gate structure 130′ and the mask M1 have a flat upper surface.

Meanwhile, in the etch-back process, the upper surface of the back gate electrode 135 may have a downwardly convex shape (see FIG. 4B).

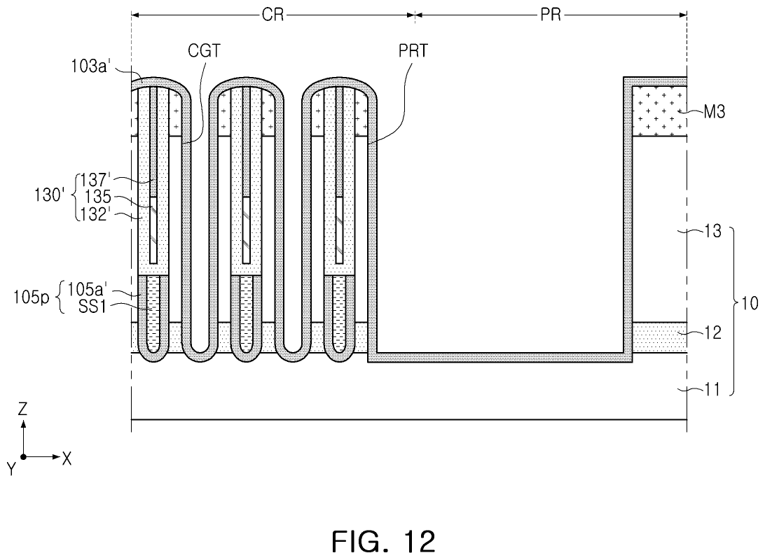

Referring to FIG. 12, a cell gate trench CGT may be formed in a memory region CR and a peripheral region trench PRT may be formed in a peripheral region PR.

The mask M1 (see FIG. 11) on the semiconductor substrate 10 may be removed, and a mask M3 used in an etching process to form the cell gate trench CGT and the peripheral region trench PRT may be formed on the semiconductor substrate 10.

Then, by utilizing the mask M3, the cell gate trenches CGT between the preliminary back gate structures 130′ may be formed in the memory region CR and the peripheral region trench PRT may be formed in the peripheral region PR.

Then, a preliminary insulating layer 103a′ may be formed in the cell gate trenches CGT and the peripheral region trench PRT. The preliminary insulating layer 103a′ may be formed to substantially conformally cover an upper surface of the preliminary back gate structure 130′, an upper surface and a side surface of the mask M3, a side surface of the upper semiconductor layer 13, a side surface of the insulating layer 12, and an upper surface of the lower semiconductor layer 11. The preliminary insulating layer 103a′ may be formed by depositing an insulating material such as silicon oxide, silicon nitride, silicon oxynitride (SiON) or silicon carbonitride (SiCN). In this example embodiment, the preliminary insulating layer 103a′ may be formed of silicon oxide.

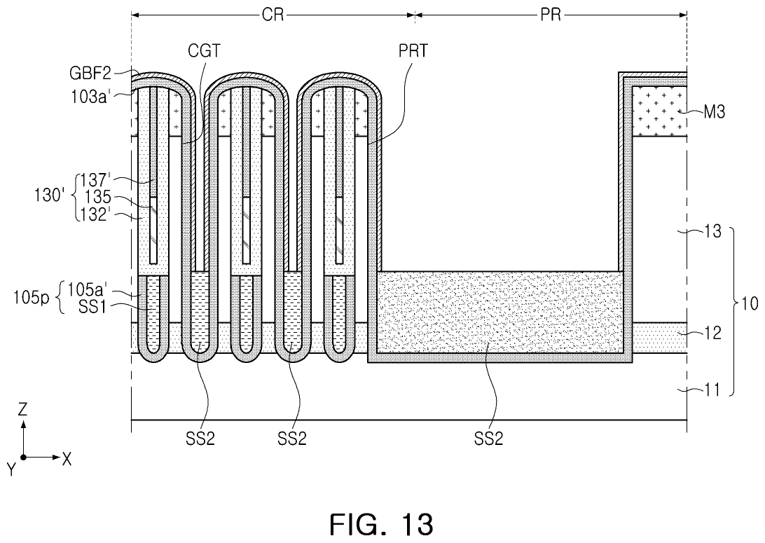

Referring to FIG. 13, in the same manner as described with reference to FIG. 9, a growth prevention film GBF2 may be formed on a surface of an upper region of the preliminary insulating layer 103a′, and a substitution structure SS2 may be grown on a surface of a lower region of the preliminary insulating layer 103a′.

As described above, the growth prevention film GBF2 may be formed on the surface of the upper region of the preliminary insulating layer 103a′ by chemical vapor deposition (CVD), and the substitution structure SS2 may be grown on the surface of the lower region of the preliminary insulating layer 103a′ by a level at which the growth prevention film GBF2 is formed.

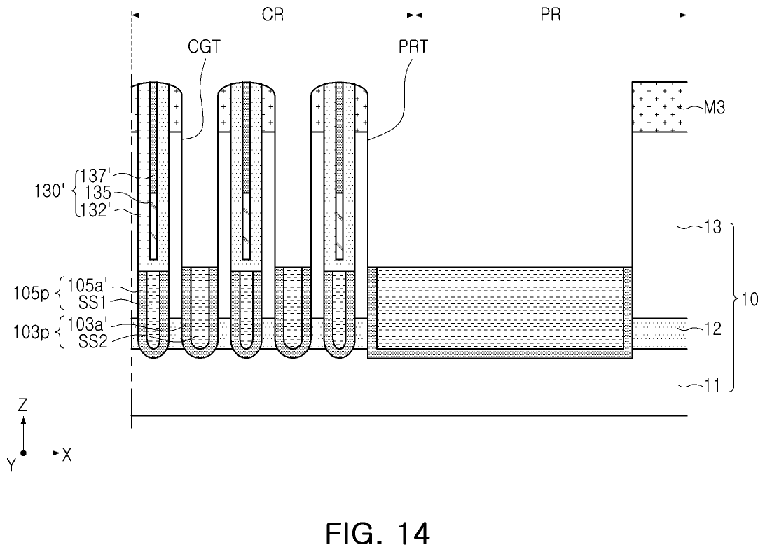

Referring to FIG. 14, in the same manner as described with reference to FIG. 10, the upper region of the preliminary insulating layer 103a′ and the growth prevention film GBF2 (see FIG. 13) may be removed.

Referring to FIG. 13 and FIG. 14 together, the upper region of the preliminary insulating layer 103a′ and the growth prevention film GBF2 in the upper region may be removed in an etching process. Accordingly, a preliminary first separation structure 103p including the preliminary insulating layer 103a′ and the substitution structure SS2 may be formed in the lower region of the cell gate trenches CGT. Meanwhile, by the etching process, the preliminary first separation structure 103p may have a downwardly convex upper surface (see FIG. 4A).

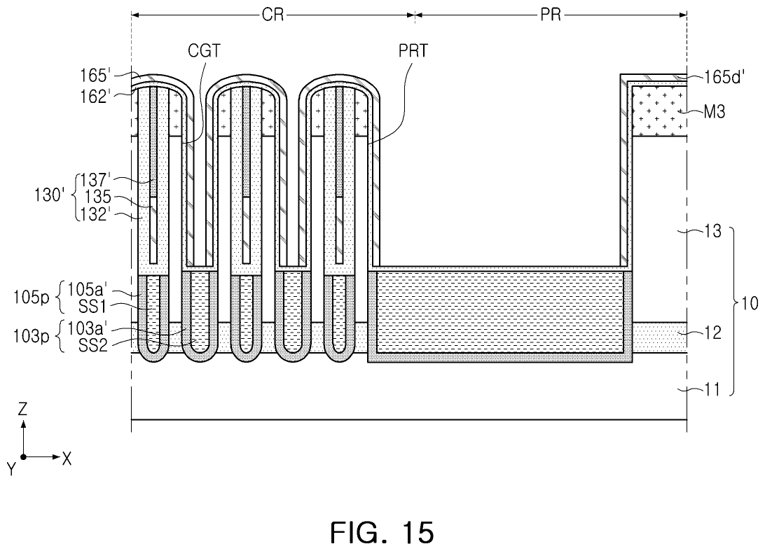

Referring to FIG. 15, a preliminary cell gate dielectric layer 162′ may be formed on sidewalls and lower surfaces of each of the cell gate trenches CGT and the peripheral region trench PRT, and a conductive material may be deposited on a surface of the preliminary cell gate dielectric layer 162′, thus forming a preliminary cell gate electrode layer 165′. Meanwhile, the conductive material deposited in the peripheral region PR may be referred to as a dummy gate electrode layer 165d′.

Then, an etching process, for example, an anisotropic etching process, may be performed so that the preliminary cell gate electrode layers 165′ may be spaced apart from each other on a lowermost surface of the preliminary cell gate dielectric layer 162′ in the first horizontal direction (X-direction), and accordingly, a portion of the preliminary cell gate electrode layer 165′ on the lowermost surface of the preliminary cell gate dielectric layer 162′ may be removed.

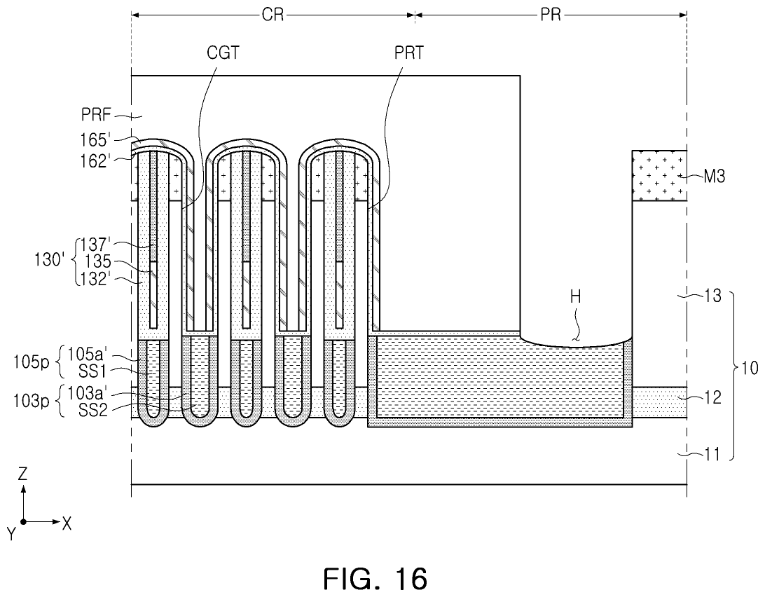

Referring to FIG. 16, a resist film PRF covering the cell gate trenches CGT and a portion of the peripheral region trench PRT may be formed, and a portion of the preliminary cell gate dielectric layer 162′ not covered by the resist film PRF and the dummy gate electrode layer 165′ in the peripheral region PR may be removed.

As the portion of the preliminary cell gate dielectric layer 162′ is removed, a groove H may be formed in an upper region of the substitution structure SS2 in the peripheral region trench PRT. Meanwhile, the resist film PRF may be a photoresist layer including a photoresist material. Then, the resist film (PRF) may be removed in an ashing process.

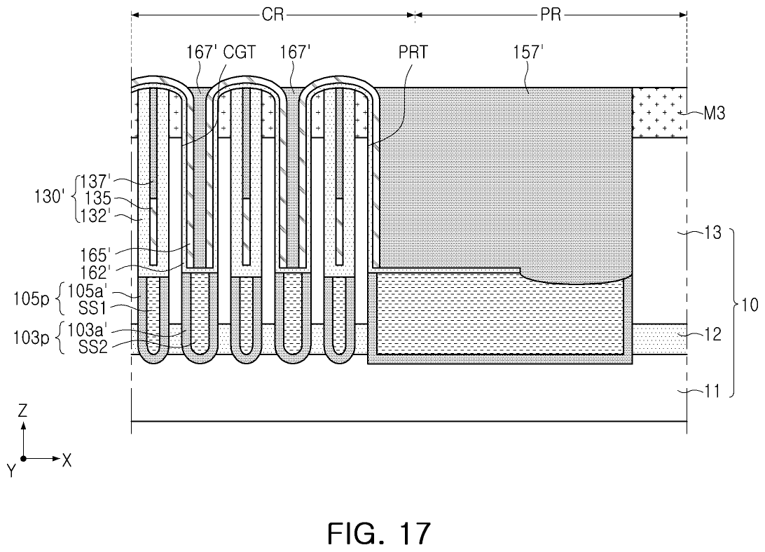

Referring to FIG. 17, a preliminary gate capping layer 167′ may be formed by filling the cell gate trenches CGT with an insulating material.

The preliminary gate capping layer 167′ may be formed by filling the cell gate trenches CGT with the insulating material such as silicon oxide, silicon nitride, silicon oxynitride (SiON), or silicon carbonitride (SiCN). In an example embodiment, the preliminary gate capping layer 167′ may be formed of silicon nitride. Meanwhile, the insulating material layer filled in the peripheral region trench PRT may be referred to as the preliminary insulating pattern 157′.

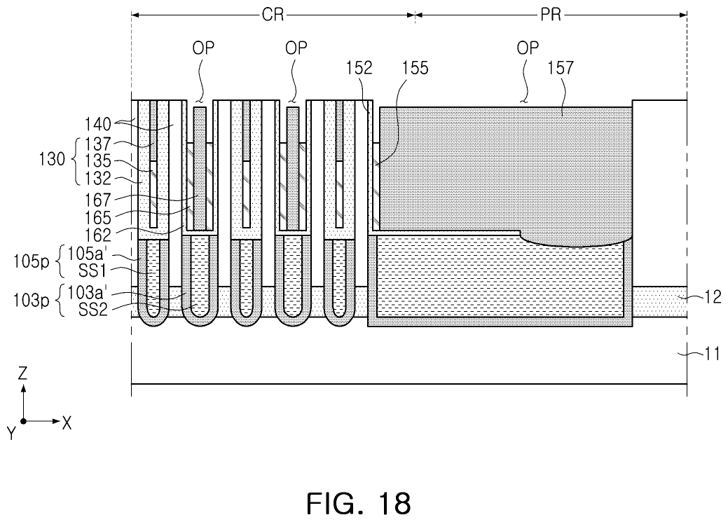

Referring to FIG. 18, the mask M3 (see FIG. 17) may be removed by performing a planarization process.

In the planarization process, the mask M3 in the memory region CR and the peripheral region PR may be removed. Accordingly, the back gate structure 130 and the vertical active pattern 140 may be defined in the memory region CR.

Then, a portion of the preliminary cell gate electrode layer 165′ of FIG. 17 may be removed by performing an etch-back process. Accordingly, the gate electrodes 165 may be defined in the memory region CR, and the conductive pattern 155 may be defined in the peripheral region PR.

In the etch-back process, portions of upper regions of the preliminary gate capping layer 167′ and the preliminary insulating pattern 157′ of FIG. 17 may be removed to have an upper surface on a level lower than that of the upper surface of the back gate capping layer 137, relative to an upper surface of the lower semiconductor layer 11 as a reference layer. Accordingly, a plurality of openings OP may be formed in the memory region CR and the peripheral region PR. By the plurality of openings OP, the first gate capping layer 167 may be defined in the memory region CR, and the insulating pattern 157 may be defined in the peripheral region PR.

Meanwhile, in the etch-back process, the gate electrodes 165 may have a downwardly convex upper surface (see FIG. 4A).

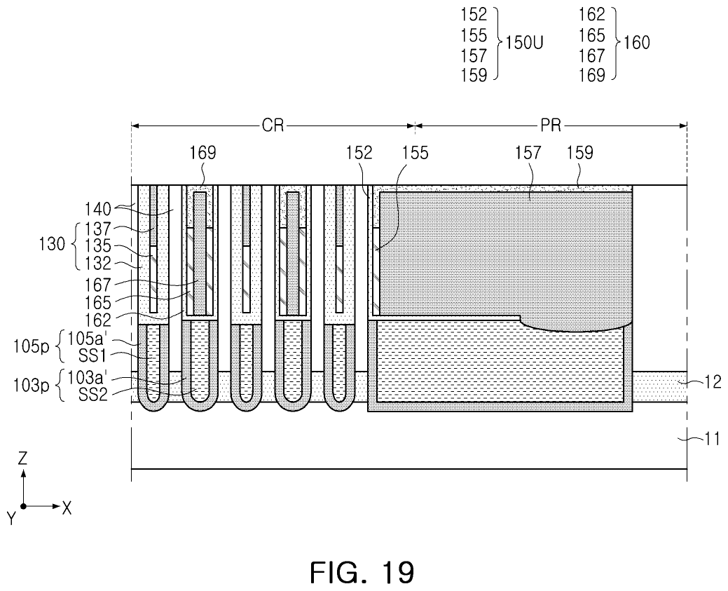

Referring to FIG. 19, a second gate capping layer 169 may be formed in the memory region CR and an insulating pattern 159 may be formed in the peripheral region PR.

Referring to FIG. 18 and FIG. 19 together, the plurality of openings OP may be filled with an insulating material and the planarization process may be performed, thus forming the second gate capping layer 169 in the memory region CR and the insulating pattern 159 in the peripheral region PR. Accordingly, the cell gate structure 160 may be defined in the memory region CR. Additionally, the upper insulating pattern 150U including a plurality of insulating patterns 152, 157 and 159 and the conductive pattern 155 may be defined in the peripheral region PR.

The second gate capping layer 169 and the insulating pattern 159 may be formed by filling the plurality of openings OP with an insulating material such as silicon oxide, silicon nitride, silicon oxynitride (SiON), or silicon carbonitride (SiCN). In an example embodiment, the second gate capping layer 169 and the insulating pattern 159 may be formed of silicon nitride.

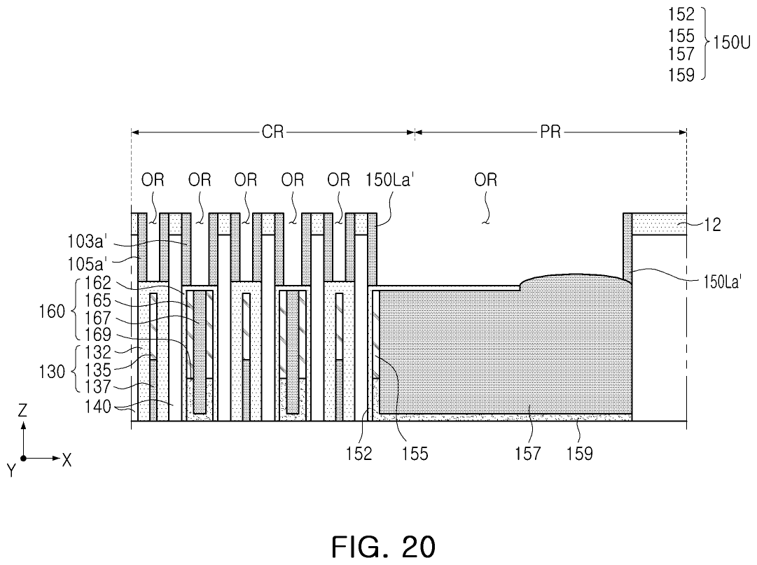

Referring to FIG. 20, the substitution structures SS1 and SS2 of the preliminary first and second separation structures 103p and 105p (see FIG. 19) may be removed.

Referring to FIG. 19 and FIG. 20 together, the preliminary semiconductor structure in FIG. 19 may be flipped upside down so that a lower surface of the lower semiconductor layer 11 may face up.

Then, the lower semiconductor layer 11 and portions of the preliminary insulating layers 103a′ and 105a′ may be removed by performing a planarization process so that surfaces of the substitution structures SS1 and SS2 may be exposed. Accordingly, preliminary liner patterns 150La′ may be defined in the peripheral region PR.

Then, the substitution structures SS1 and SS2 exposed by the planarization process may be selectively removed. Accordingly, the plurality of openings OR may be defined on the cell gate structure 160 and the back gate structure 130 of the memory region CR, and on the upper insulating pattern 150U of the peripheral region PR.

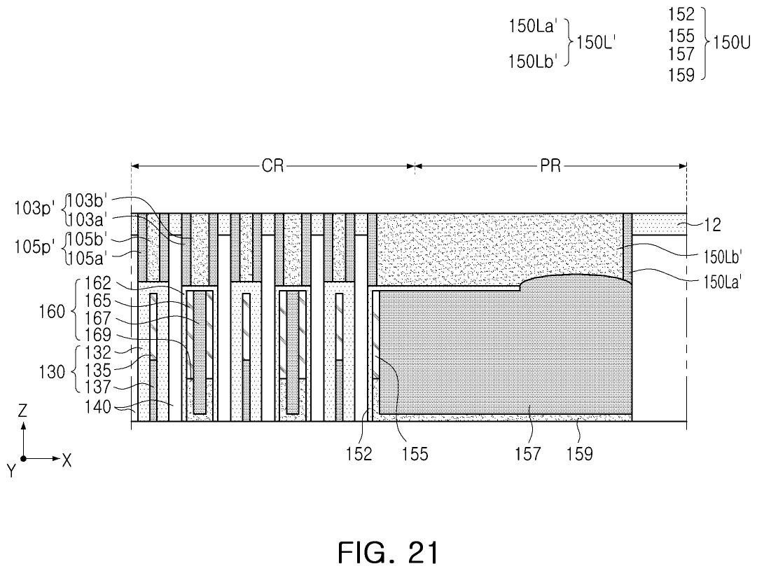

Referring to FIG. 21, the plurality of openings OR (see FIG. 20) may be filled with an insulating material, thus forming first and second preliminary capping layers 103b′ and 105b′ and a preliminary capping pattern 150Lb′.

Referring to FIG. 20 and FIG. 21 together, the plurality of openings OR may be filled with the insulating material, thus forming first and second preliminary capping layers 103b′ and 105b′ and a preliminary capping pattern 150Lb′.

Accordingly, a preliminary first separation structure 103p′ including the preliminary insulating layers 103a′ and the first preliminary capping layer 103b′, and a preliminary second separation structure 105p′ including the preliminary insulating layers 105a′ and the second preliminary capping layer 105b′ may be defined in the memory region CR. Additionally, a preliminary lower insulating pattern 150L′ including the preliminary liner patterns 150La′ and the preliminary capping pattern 150Lb′ may be defined in the peripheral region PR.

The first and second preliminary capping layers 103b′ and 105b′ and the preliminary capping pattern 150Lb′ may be formed by filling the plurality of openings OR with an insulating material such as silicon oxide, silicon nitride, silicon oxynitride (SiON) or silicon carbonitride (SiCN). In an example embodiment, the first and second preliminary capping layers 103b′ and 105b′ and the preliminary capping pattern 150Lb′ may be formed of silicon nitride.

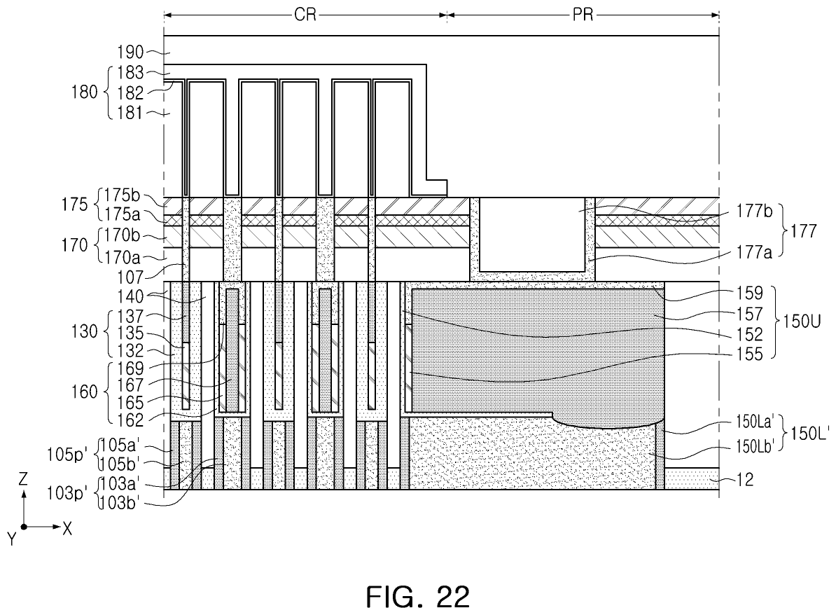

Referring to FIG. 22, cell upper source/drain patterns 170, contact plugs 175, insulating structures 177, information storage structures 180, and insulating layer 190 may be formed.

Referring to FIG. 21 and FIG. 22 together, the preliminary semiconductor structure in FIG. 21 may be flipped upside down so that lower surfaces of the vertical active pattern 140 and lower surfaces of the gate capping layers 137 and 169 may face up.

Subsequently, a first semiconductor layer covering the upper surfaces of the vertical active pattern 140 and the upper surfaces of the gate capping layers 137 and 169, a second semiconductor layer on the first semiconductor layer, and an insulating layer (not shown) on the second semiconductor layer may be formed sequentially.

Then, separation patterns 107 defining side surfaces of the first and second semiconductor layers and the insulating layer may be formed. Accordingly, the first semiconductor layer may be defined as the first cell upper source/drain pattern 170a, and the second semiconductor layer may be defined as the second cell upper source/drain pattern 170b.

Subsequently, the insulating structure 177 may be formed. The insulating structure 177 may penetrate through (i.e., extend in) the first and second semiconductor layers. The insulating structure 177 may include an insulating pattern 177b and an insulating liner 177a covering a side surface and a lower surface of the insulating pattern 177b. The insulating pattern 177b may include oxide, and the insulating liner 177a may include nitride.

Subsequently, the insulating layer may be removed to expose an upper surface of the second cell upper source/drain pattern 170b and a side surface of an upper region of the insulating liner 177a, and a metal semiconductor compound layer 175a on the second cell upper source/drain pattern 170b and plug patterns 175b on the metal semiconductor compound layer 175a may be formed sequentially.

Subsequently, information storage structure 180 may be formed. The information storage structure 180 may include first electrodes 181 connected to the plug patterns 175b and extending in the vertical direction (Z-direction), second electrodes 183 on side surfaces and upper surfaces of each of the first electrodes 181, and a dielectric layer 182 between the first electrodes 181 and the second electrodes 183.

Then, an insulating layer 190 covering the information storage structure 180 in the memory region CR and the insulating structure 177 in the peripheral region PR may be formed.

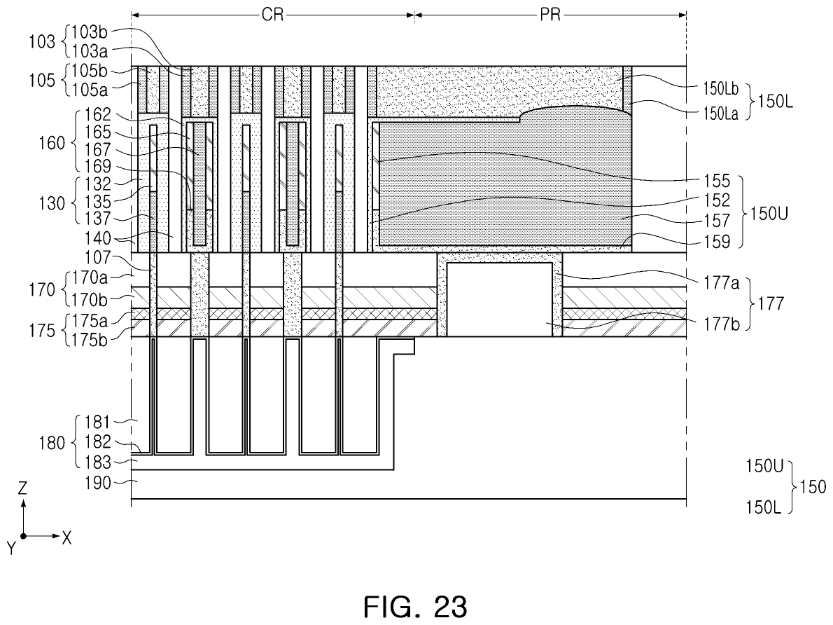

Referring to FIG. 23, the insulating layer 12 of the semiconductor substrate 10 may be removed.

Referring to FIG. 22 and FIG. 23 together, the preliminary semiconductor structure in FIG. 22 may be flipped upside down so that a lower surface of the insulating layer 12 may face up.

The insulating layer 12 may be removed by performing a planarization process. Accordingly, the first separation structures 103 on the cell gate structures 160 and the second separation structures 105 on the back gate structures 130 may be defined in the memory region CR. Additionally, the lower insulating pattern 150L may be defined in the peripheral region PR, and accordingly, the insulating structure 150 including upper and lower insulating patterns 150U and 150L, respectively, may be defined.

Although not explicitly illustrated, referring to FIG. 2, the cell lower source/drain pattern 110, the first conductive layer 120a, and the second conductive layer 120b may be formed sequentially on the first and second separation structures 103 and 105 in the memory region CR and the insulating structure 150 in the peripheral region PR.

Then, the insulating layer 101 and the insulating pattern 102 may be formed. The insulating layer 101 may cover a lower surface and a side surface of the bit line 120 and may cover a side surface and an upper surface of the insulating pattern 102. The insulating layer 101 may include nitride, and the insulating pattern 102 may include oxide. Then, the insulating layer 195 may be formed on the insulating layer 101 and the insulating pattern 102, thus forming the semiconductor device 100.

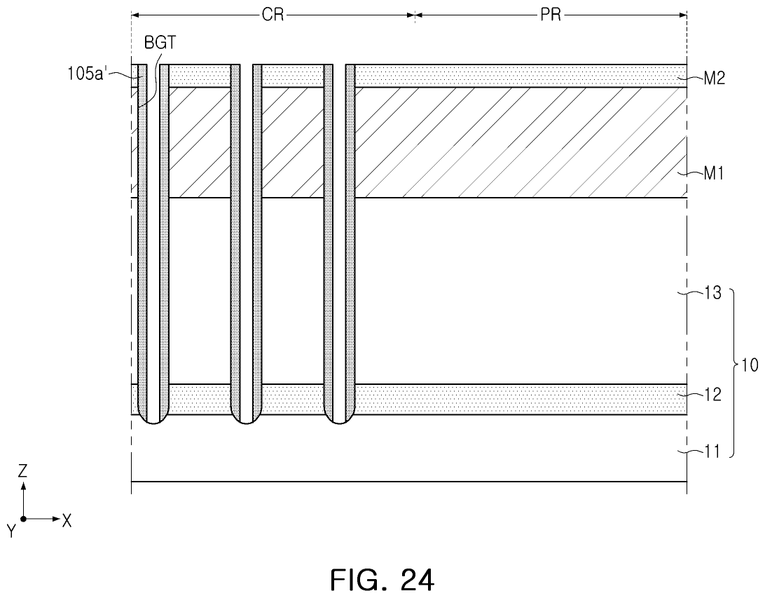

FIGS. 24 to 30 are vertical cross-sectional views illustrating intermediate processes in a manufacturing method of a semiconductor device 100b according to an example embodiment. FIG. 24 may be a process diagram following FIG. 8.

Referring to FIG. 24, an upper surface of a lower semiconductor layer 11 may be exposed through back gate trenches BGT.

A preliminary insulating layer 105a′ on a lower surface of the back gate trench BGT may be removed using an etching process so that the upper surface of the lower semiconductor layer 11 may be exposed. Accordingly, the preliminary insulating layer 105a′ on a mask M2 may also be removed.

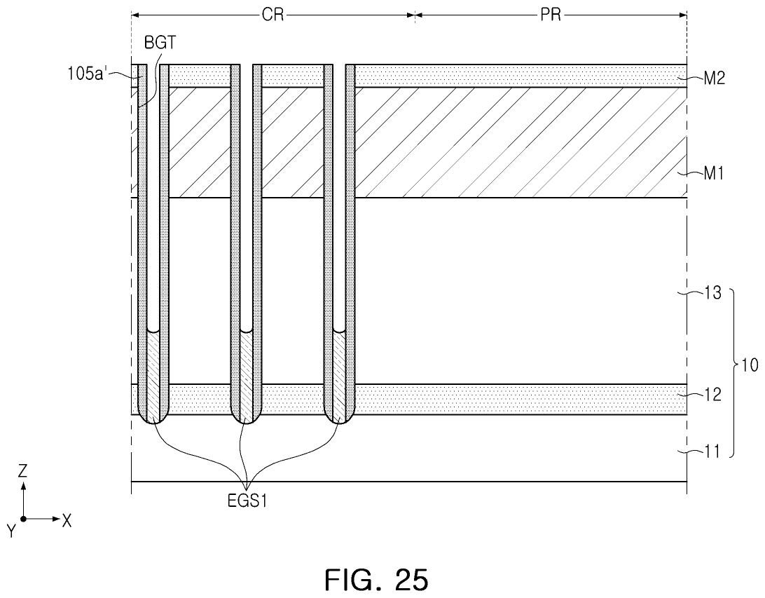

Referring to FIG. 25, a first semiconductor pattern EGS1 may be formed from the upper surface of the lower semiconductor layer 11.

The first semiconductor pattern EGS1 may be formed of epitaxial silicon grown from the upper surface of the lower semiconductor layer 11 exposed by the etching process according to FIG. 24.

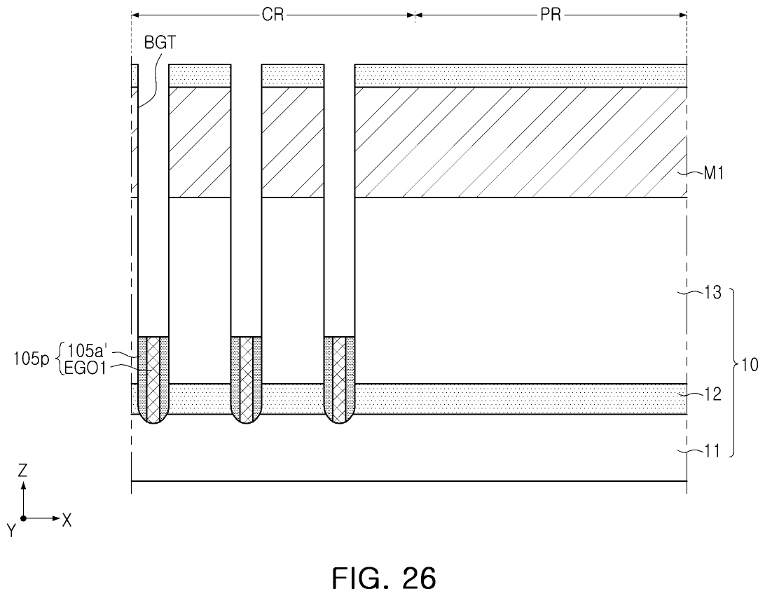

Referring to FIG. 26, a first oxide pattern EGO1 may be formed.

Through an etch-back process, the first semiconductor pattern EGS1 may be reduced to a desired height.

The first oxide pattern EGO1 may be formed by oxidizing the first semiconductor pattern EGS1. The first oxide pattern EGO1 may be formed of silicon oxide.

Subsequently, similarly to what was described with reference to FIG. 10, the upper portion of the preliminary insulating layer 105a′ of may be removed, and accordingly, a preliminary second separation structure 105p including the preliminary insulating layer 105a′ and the first oxide pattern EGO1 in the lower region of the back gate trench BGT may be formed.

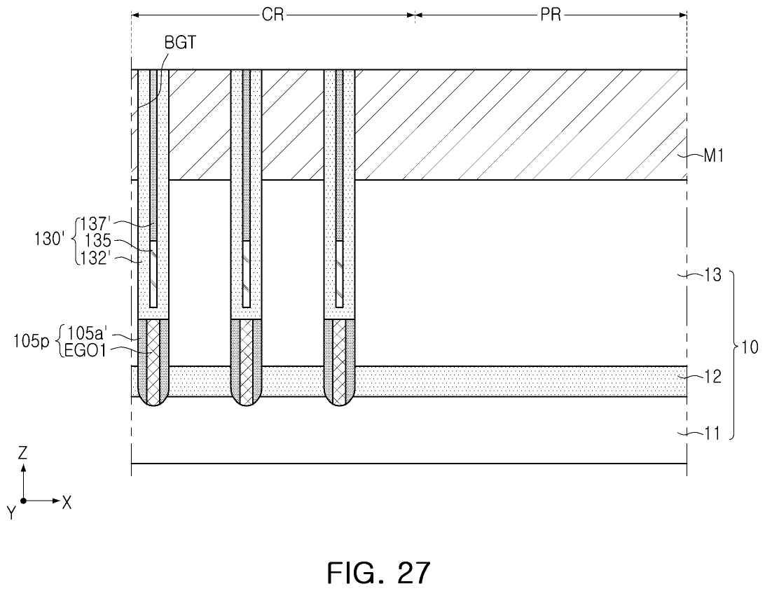

Referring to FIG. 27, similarly to what was described with reference to FIG. 11, a preliminary back gate structure 130′ may be formed in the back gate trench BGT.

A preliminary back gate insulating layer 132′ may be formed on a sidewall and a lower surface of the back gate trench BGT. Next, the back gate trench BGT may be filled with a conductive material, and then, an etch-back process may be performed to form a back gate electrode 135. Next, the back gate trench BGT may be filled with the insulating material to cover an upper surface of the back gate electrode 135, thus forming a preliminary back gate capping layer 137′. Then, a planarization process may be performed so that the preliminary back gate structure 130′ and the mask M1 have a flat upper surface.

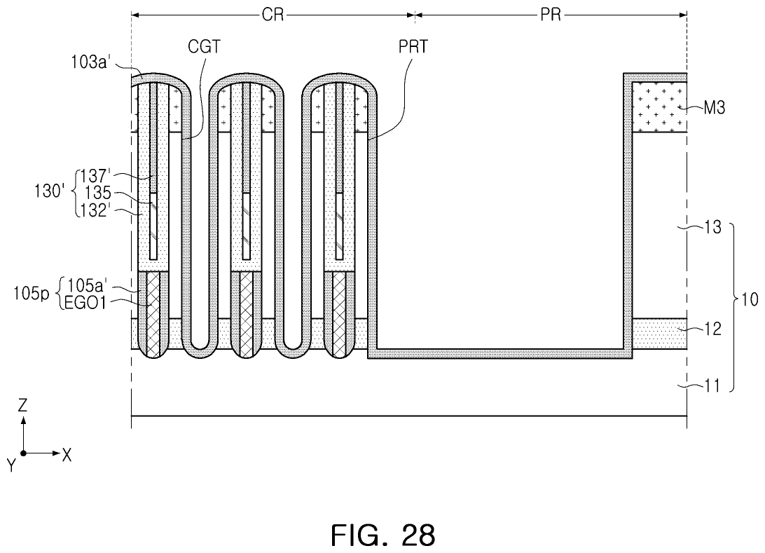

Referring to FIG. 28, similarly to what was described with reference to FIG. 12, a cell gate trench CGT in a memory region CR and a peripheral region trench PRT in a peripheral region PR may be formed.

The mask M1 on the semiconductor substrate 10 may be removed, and a mask M3 used in the etching process for forming the cell gate trench CGT and the peripheral region trench PRT may be formed on the semiconductor substrate 10.

Then, the cell gate trenches CGT between the preliminary back gate structures 130′ in the memory region CR and the peripheral region trenches PRT in the peripheral region PR may be formed using the mask M3,

Then, a preliminary insulating layer 103a′ may be formed in the cell gate trenches CGT and the peripheral region trench PRT. The preliminary insulating layer 103a′ may be formed to substantially conformally cover an upper surface of the preliminary back gate structure 130′, an upper surface and a side surface of the mask M3, a side surface of the upper semiconductor layer 13, a side surface of the insulating layer 12 and an upper surface of the lower semiconductor layer 11.

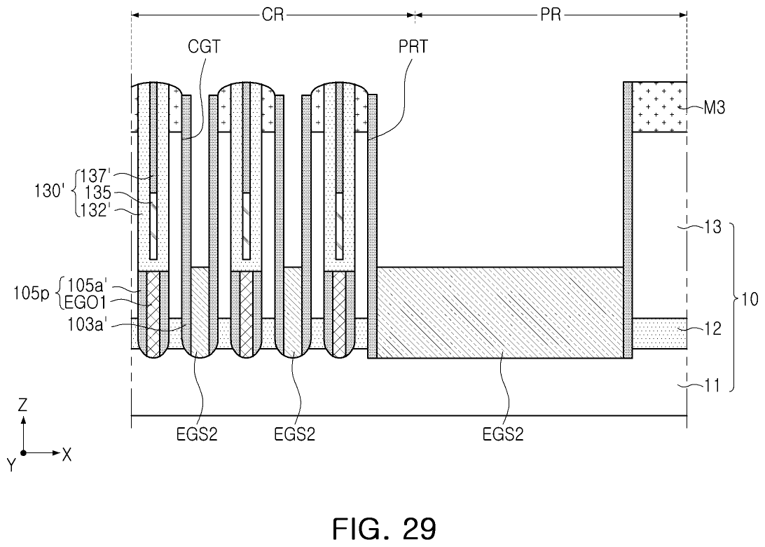

Referring to FIG. 29, an upper surface of the lower semiconductor layer 11 may be exposed, and a second semiconductor pattern EGS2 may be formed from the upper surface of the lower semiconductor layer 11.

Similarly to what was described with reference to FIG. 24, the preliminary insulating layer 103a′ on lower surfaces of the cell gate trenches CGT and a lower surface of the peripheral region trench PRT may be removed using an etching process so that the upper surface of the lower semiconductor layer 11 may be exposed. Accordingly, the preliminary insulating layer 103a′ on the mask M3 may also be removed.

Similarly to what was described with reference to FIG. 25, a second semiconductor pattern EGS2 may be formed from the upper surface of the lower semiconductor layer 11. The second semiconductor pattern EGS2 may be formed of epitaxial silicon.

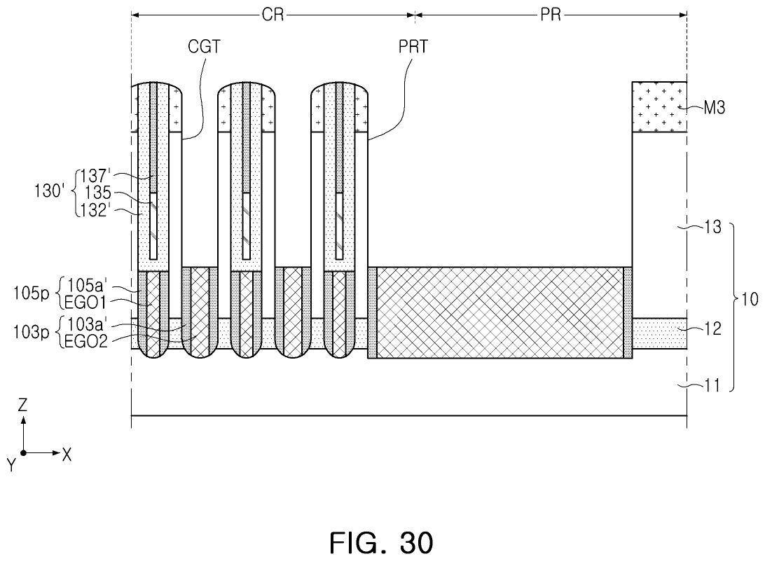

Referring to FIG. 30, the second oxide pattern EGO2 may be formed.

Similarly to what was described with reference to FIG. 26, through the etch-back process, the second semiconductor pattern EGS2 may be reduced to a desired height.

The second oxide pattern EGO2 may be formed by oxidizing the second semiconductor pattern EGS2. The second oxide pattern EGO2 may be formed of silicon oxide.

Next, similarly to what was described with reference to FIG. 14, the preliminary insulating layer 103a′ in the upper regions of the cell gate trenches CGT and the peripheral region trench PRT may be removed, and accordingly, a preliminary first separation structure 103p including the second oxide pattern EGO2 and the preliminary insulating layer 103a′ and a preliminary second separation structure 105p including the first oxide pattern EGO1 and the preliminary insulating layer 105a′ may be formed.

Then, through the process order described with reference to FIGS. 15 to 19, gate structures 130 and 160 and an upper insulating pattern 150U may be formed.

Hereafter, unlike the process described with reference to FIGS. 20 and 21, in this example embodiment, the first and second oxide patterns EGO1 and EGO2 may not be removed. In other words, the preliminary semiconductor structure that has undergone the process described with reference to FIG. 19 may be flipped upside down so that the lower surface of the lower semiconductor layer 11 may face up, and surfaces of the first and second oxide patterns EGO1 and EGO2 may be exposed using the planarization process.

Next, a semiconductor device 100b may be formed through the process described with reference to FIG. 22 and additional processes after the above-described process.

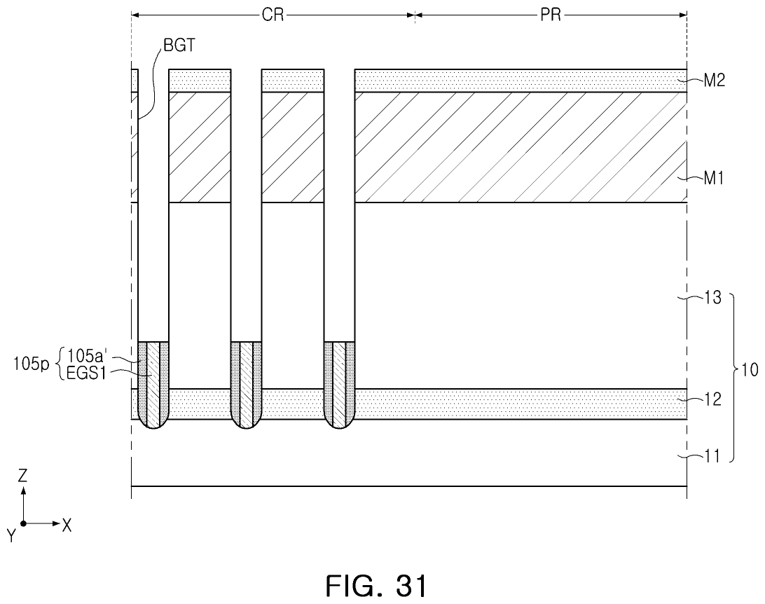

FIGS. 31 to 36 are vertical cross-sectional views illustrating intermediate processes in a method of manufacturing a semiconductor device 100c according to an example embodiment of the present disclosure. FIG. 31 may be a process diagram following the process shown in FIG. 25.

Referring to FIG. 31, a first semiconductor pattern EGS1 may be formed from an upper surface of a lower semiconductor layer 11.

Similarly to what was described with reference to FIG. 25, the first semiconductor pattern EGS1 may be formed of epitaxial silicon grown from the upper surface of the lower semiconductor layer 11 exposed by the etching process described with reference to FIG. 24.

Next, the first semiconductor pattern EGS1 may be reduced to a desired height through an etch-back process. Accordingly, a preliminary second separation structure 105p in a back gate trench BGT may be defined.

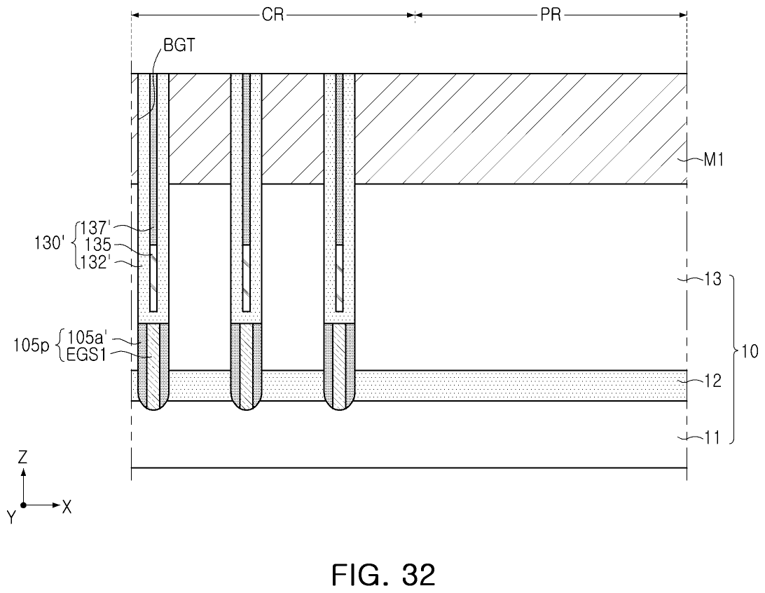

Referring to FIG. 32, similarly to what was described with reference to FIG. 27, a preliminary back gate structure 130′ may be formed in the back gate trench BGT.

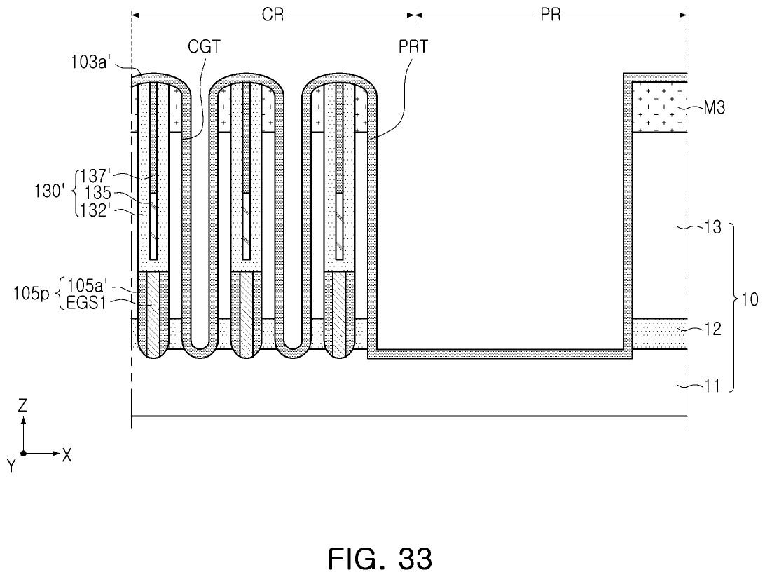

Referring to FIG. 33, similarly to what was described with reference to FIG. 28, a cell gate trench CGT in a memory region CR and a peripheral region trench PRT in a peripheral region PR may be formed. Then, the preliminary insulating layer 103a′ may be formed in the cell gate trenches CGT and the peripheral region trench PRT.

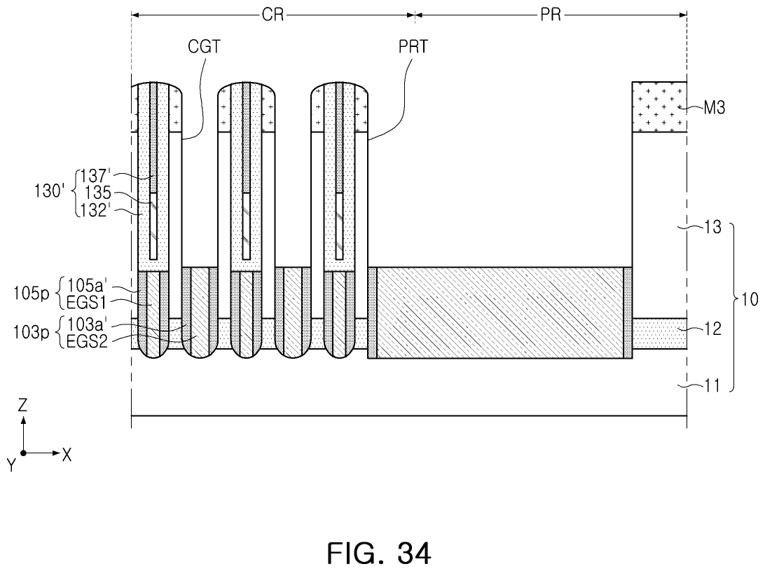

Referring to FIG. 34, similarly to what was described with reference to FIG. 29, the preliminary insulating layer 103a′ on lower surface of the cell gate trenches CGT maybe removed to expose the upper surface of the lower semiconductor layer 11, and a second semiconductor pattern EGS2 may be formed from the upper surface of the lower semiconductor layer 11. Accordingly, a preliminary first separation structure 103p in the cell gate trenches CGT may be defined.

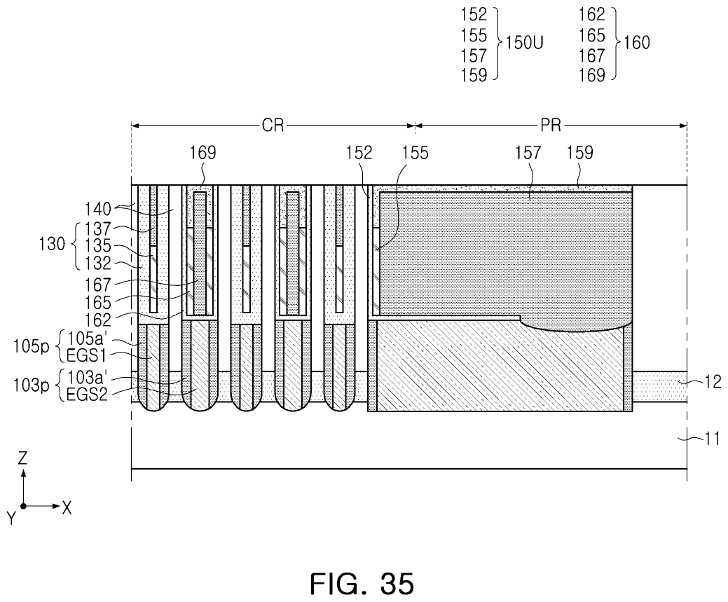

Referring to FIG. 35, similarly to what was described with reference to FIGS. 14 to 19, gate structures 130 and 160 and an upper insulating pattern 150U may be formed.

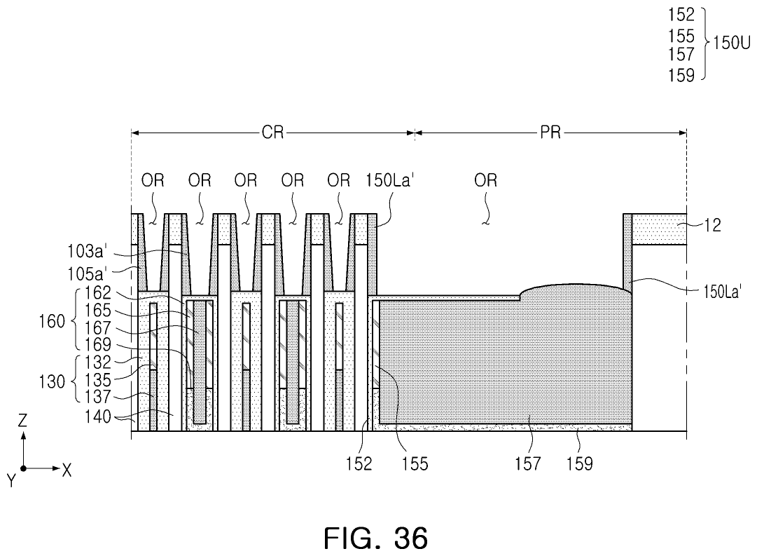

Referring to FIG. 36, similarly to what was described with reference to FIG. 20, the first and second semiconductor patterns EGS1 and EGS2 of each of the preliminary first and second separation structures 103p and 105p, respectively, may be removed.

Referring to FIG. 35 and FIG. 36 together, the preliminary semiconductor structure in FIG. 35 may flipped upside down so that the lower surface of the lower semiconductor layer 11 may face up.

Then, the lower semiconductor layer 11 and portions of the preliminary insulating layers 103a′ and 105a′ may be removed by performing a planarization process so that surfaces of the first and second semiconductor patterns EGS1 and EGS2 may be exposed. Accordingly, preliminary liner patterns 150La′ may be defined in the peripheral region PR.

Then, the first and second semiconductor patterns EGS1 and EGS2 exposed by the planarization process may be removed. The first and second semiconductor patterns EGS1 and EGS2 may be selectively removed by an etching process using a difference in etch selectivity for the insulating layers 103a′, 105a′, 12 (see FIG. 35). The etching process may be, for example, a wet etching process. Accordingly, the preliminary insulating layers 103a′ and 105a′ may have a shape in which a width increases as the preliminary insulating layers 103a′ and 105a′ approach the gate structures 130 and 160 (see FIGS. 7A and 7B together).

Then, a semiconductor device 100c or 100d may be formed through the processes described with reference to FIGS. 21 to 23 and additional processes after the above-described process.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device, comprising:
a bit line structure;
a first active pattern and a second active pattern on the bit line structure and spaced apart from each other in a first direction parallel to an upper surface of the bit line structure;
a cell gate structure between the first active pattern and the second active pattern; and
a first separation structure between the bit line structure and the cell gate structure,
wherein the cell gate structure comprises:
a first gate electrode adjacent to the first active pattern;
a second gate electrode adjacent to the second active pattern;
an insulating layer between the first and second gate electrodes; and
a gate dielectric layer on the first and second gate electrodes and at least a portion of the insulating layer;
wherein the gate dielectric layer comprises:
first and second vertical portions, the first vertical portion between the first active pattern and the first gate electrode, and the second vertical portion between the second active pattern and the second gate electrode; and
a first intermediate portion connected to the first and second vertical portions and between the first and second gate electrodes and the first separation structure, and
wherein the first separation structure comprises:
first liners spaced apart from each other in the first direction between the first intermediate portion of the gate dielectric layer and the bit line structure; and
a first capping layer between the first liners.

2. The semiconductor device of claim 1, wherein each of the first and second active patterns comprises:
a first source/drain region electrically connected to the bit line structure;
a second source/drain region on a level higher than a level of the first source/drain region, relative to the upper surface of the bit line structure; and
a vertical channel region between the first and second source/drain regions.

3. The semiconductor device of claim 2, wherein at least a portion of the vertical channel region faces the first and second gate electrodes.

4. The semiconductor device of claim 1, wherein the gate dielectric layer and the first liners of the first separation structure comprise an oxide, and
the first capping layer of the first separation structure comprises a nitride.

5. The semiconductor device of claim 1, wherein a thickness of the gate dielectric layer in a second direction perpendicular to the upper surface of the bit line structure is different from a thickness in the first direction of each of the first liners of the first separation structure.

6. The semiconductor device of claim 1, wherein an upper surface of the first separation structure is convex toward the upper surface of the bit line structure, and
the first intermediate portion of the gate dielectric layer is convex toward the upper surface of the bit line structure.

7. The semiconductor device of claim 6, wherein lower regions of the first and second gate electrodes and a lower region of the insulating layer have a convex shape toward the upper surface of the bit line structure.

8. The semiconductor device of claim 1, wherein upper surfaces of the first and second gate electrodes are convex toward the first separation structure.

9. The semiconductor device of claim 1, wherein the gate dielectric layer, the first liners, and the first capping layer comprise an oxide.

10. The semiconductor device of claim 1, wherein a width of each of the first liners of the first separation structure in the first direction decreases as a distance in a second direction, perpendicular to the upper surface of the bit line structure, from the first intermediate portion of the gate dielectric layer increases.

11. The semiconductor device of claim 10, wherein a lower surface of each of the first liners are in contact with the upper surface of the bit line structure.

12. The semiconductor device of claim 1, wherein a vertical distance from the upper surface of the bit line structure to lower surfaces of the first and second gate electrodes ranges from 10 nm to 100 nm.

13. The semiconductor device of claim 1, wherein a vertical height of the first separation structure, relative to the upper surface of the bit line structure as a reference, ranges from 10 nm to 90 nm.

14. The semiconductor device of claim 1, further comprising:
a third active pattern on the bit line structure and spaced apart from the second active pattern in the first direction;
a back gate structure between the second active pattern and the third active pattern; and
a second separation structure between the bit line structure and the back gate structure,
wherein the back gate structure comprises:
a back gate electrode; and
a back gate dielectric layer on at least a portion of the back gate electrode,
wherein the back gate dielectric layer comprises:
third and fourth vertical portions, the third vertical portion between the second active pattern and the back gate electrode and the fourth vertical portion between the third active pattern and the back gate electrode; and
a second intermediate portion connected to the third and fourth vertical portions and between the back gate electrode and the second separation structure, and
wherein the second separation structure comprises:
second liners spaced apart from each other in the first direction between the second intermediate portion of the back gate dielectric layer and the bit line structure; and
a second capping layer between the second liners.

15. The semiconductor device of claim 14, wherein a thickness of the back gate dielectric layer in a second direction perpendicular to the upper surface of the bit line structure is different from a thickness in the first direction of each of the second liners of the second separation structure.

16. A semiconductor device, comprising:
a first vertical active pattern and a second vertical active pattern spaced apart from each other;
a gate structure between the first and second vertical active patterns; and
an insulating structure on the gate structure,
wherein the gate structure comprises:
at least one gate electrode;
an insulating layer on the at least one gate electrode; and
a gate dielectric layer on the at least one gate electrode and at least a portion of the insulating layer,
wherein the gate dielectric layer comprises:
a first portion between the first vertical active pattern and the at least one gate electrode;
a second portion between the second vertical active pattern and the at least one gate electrode; and
a third portion connected to the first and second portions and between the at least one gate electrode and the insulating structure, and
wherein the insulating structure comprises:
liners spaced apart from each other on the third portion of the gate dielectric layer; and
a capping layer between the liners.

17. The semiconductor device of claim 16, wherein the at least one gate electrode of the gate structure comprises a plurality of cell gate electrodes,
wherein the plurality of cell gate electrodes comprises:
a first cell gate electrode adjacent to the first vertical active pattern; and
a second cell gate electrode adjacent to the second vertical active pattern, and
wherein the insulating layer of the gate structure is between the first and second cell gate electrodes,
the first portion of the gate dielectric layer is between the first vertical active pattern and the first cell gate electrode,
the second portion is between the second vertical active pattern and the second cell gate electrode, and
at least a portion of the third portion is in contact with lower surfaces of the first and second cell gate electrodes and a lower surface of the insulating layer.

18. The semiconductor device of claim 16, wherein the insulating layer of the gate structure is on an upper portion of the at least one gate electrode, and
at least a portion of the third portion of the gate dielectric layer is in contact with a lower surface of the at least one gate electrode.

19. A semiconductor device, comprising:
a memory region and a peripheral region,
wherein the memory region comprises:
a first vertical active pattern and a second vertical active pattern spaced apart from each other;
a cell gate structure between the first and second vertical active patterns; and
a separation structure on the cell gate structure,
wherein the cell gate structure comprises:
a first gate electrode adjacent to the first vertical active pattern;
a second gate electrode adjacent to the second vertical active pattern;
an insulating layer between the first and second gate electrodes; and
a gate dielectric layer on the first and second gate electrodes and at least a portion of the insulating layer,
wherein the separation structure comprises:
liners spaced apart from each other on a lower surface of the gate dielectric layer; and
a capping layer between the liners,
wherein the peripheral region comprises an insulating structure including a lower portion and an upper portion on the lower portion,
wherein the lower portion of the insulating structure comprises:
liner patterns spaced apart from each other on a lower surface of the upper portion; and
a capping pattern between the liner patterns.

20. The semiconductor device of claim 19, wherein an upper surface of the lower portion of the insulating structure and an upper surface of the separation structure are substantially coplanar.
